(19) United States
(12) Patent Application Publication
(10) Pub. No.: US 2012/0288347 A1
(43) Pub. Date: Nov. 15, 2012

(54) CONVEYING DEVICE AND VACUUM APPARATUS

(75) Inventor: Hirofumi MINAMI, Chigasaki-shi (JP)

(73) Assignee: ULVAC, INC., Chigasaki-shi (JP)

(21) Appl. No.: 13/474,991

(22) Filed: May 18, 2012

Related U.S. Application Data
(63) Continuation of application No. PCT/JP10/69413, filed on Nov. 1, 2010.

(30) Foreign Application Priority Data
Nov. 20, 2009 (JP) 2009-265356

(51) Int. Cl. H01L 21/677; B25J 11/00

(52) U.S. Cl. 414/217; 414/751.1

(57) ABSTRACT

A conveying device includes an extensible link mechanism having a plurality of arms receiving power from a drive source, a mounting section for mounting a substrate, connected to an operation tip section of the link mechanism through third left and right arms. A downstream-side pressing mechanism making contact with and pressing a side portion of the substrate toward the link mechanism in accordance with the operation of the link mechanism is provided in an area of the mounting section on the downstream side in the direction of substrate conveyance. An upstream-side pressing mechanism making contact with and pressing the side portion of the substrate in the direction of substrate conveyance in accordance with the operation of the link mechanism is provided in an area of the mounting section on the upstream side in the direction of substrate conveyance.

This application is a continuation of international Application No. PCT/JP2010/069413, filed on Nov. 1, 2010, which claims priority to Japan Patent Application No. 2009-265356, filed on Nov. 20, 2009. The contents of the prior applications are herein incorporated by reference if their entireties.

### BACKGROUND

The present invention generally relates to conveying device which conveys an object to be conveyed (such as, a substrate) and more in particular to a conveying device that is suitable for a vacuum apparatus having a plurality of process chambers (such as, a semiconductor manufacturing apparatus).

In the field of semiconductor manufacturing, a substrate conveying device 201 (see, FIGS. 19 and 20) has been used heretofore.

The substrate conveying device 201 has a drive section 202, an arm section 203 which is connected to the drive section 202 and includes a plurality of arms, and an end effector 204 which is connected to the extremity of the arm section 203. The substrate conveying device 201 supports the backside of a substrate W with the top surface of the end effector 204 and transfers the substrate W between a plurality of process chambers (not shown).

The end effector 204 is typically made of ceramics, stainless steel, or the like. When the arm section 203 is operated to extend, contract, or rotate at high speed, the end effector 204 also moves at high speed, so that there is a problem such that the acceleration on the substrate W makes the substrate W slide over the end effector 204, and the substrate W fails to be conveyed to a proper position.

The conventional technology also has a problem in that the surface of the substrate W can be contaminated with dust that occurs when the substrate W slides over the end effector 204.

It has thus been proposed, to provide a plurality of holding sections 205 on the top surface of the end effector 204 so as to make contact with the backside of the substrate W at predetermined points, as shown in FIG. 20.

The holding sections 205 are typically made of an elastic resin material (such as, rubber and elastomer), and function as anti-slip pads for suppressing a slide at the backside of the substrate W. The substrate W can thus be held in a stable conveyance position without sliding over the top surface of the end effector 204 (see, for example, JPA2002-353291).

The holding sections 205 made of an elastic resin material (such as, elastomer) effectively suppress the sliding of the substrate W when the substrate W and the ambience are relatively low in temperature (for example, 200° C. or lower). If the temperature is high (for example, 300 to 500° C.), however, there is a problem in that the holding sections 205 fail to suppress the sliding of the substrate W due to thermal alteration or deformation.

Even when the temperature is relatively low (for example, 200° C. or lower), the adhesion of the holding sections 205 may sometimes make the substrate W stick to and not properly detachable from the end effector 204. For example, there are problems such that the substrate W sticking to the holding sections 205 may be broken when the substrate W is transferred to a stage in a process chamber, and such that the substrate W cannot be conveyed to a proper position.

Moreover, since the sliding of the substrate W is suppressed in principle by the frictional force between the holding sections 205 and the substrate W, the substrate W slides over the end effector 204 when the substrate W undergoes acceleration beyond the maximum static frictional force which is determined by both the materials. Consequently, there is a problem in that it is not possible to increase the operating speed of the conveying device 201 beyond the maximum static frictional force between the holding sections 205 and the substrate W.

### SUMMARY OF THE INVENTION

The present invention has been achieved in order to solve the foregoing problems of the conventional technologies. It is thus an object of the present invention to reliably hold an object to be conveyed for the sake of high speed conveyance both in an environment where the object to be conveyed and the ambience are relatively low in temperature and in an environment where the temperature is high.

Another object of the present invention is to provide technology for reducing dust as much as possible when conveying an object to be conveyed.

The present invention has achieved the foregoing objects and provides a conveying device including an extensible link mechanism having a plurality of arms to which power from a drive source is transmitted; a mounting section for mounting an object to be conveyed, the mounting section being connected to an operating tip section of the link mechanism through a drive link section; and a downstream-side pressing mechanism provided in an area of the mounting section on a downstream side in a direction of substrate conveyance, the downstream-side pressing mechanism making contact with a side portion of the object to be conveyed so as to press the side portion of the objection to be conveyed toward the link mechanism in accordance with operation of the drive link section of the link mechanism, and the object to be conveyed being sandwiched and held from both sides in the direction of substrate conveyance by the pressing of the downstream-side pressing mechanism.

The present invention is also effective when an upstream-side pressing mechanism, which makes contact with the side portion of the object to be conveyed so as to press the object to be conveyed toward downstream side in the direction of substrate conveyance, is provided in an area of the mounting section on an upstream side in the direction of substrate conveyance.

The present invention is also effective when the downstream-side pressing mechanism includes a drive section of cam type, and a downstream-side pressing section of cam type that is driven by the drive section of cam type.

The present invention is also effective when the downstream-side pressing mechanism includes a drive section of link type, and a downstream-side pressing section of link type, the downstream-side pressing section being engaged with and driven by the drive section of link type.

The present invention provides the conveying device, which also includes two of the downstream-side pressing section, and the gripping sections provided on the respective downstream-side pressing sections are arranged to be line-symmetrical with respect to a straight line that extends in the direction of substrate conveyance through center axes of rotation of first and second drive shafts.

The present invention provides the conveying device, wherein the upstream-side pressing mechanism includes a cam drive surface provided on the drive link section of the link mechanism, and a follower mechanism section including a pressing section having a follower roller in contact with and capable of following to move the cam drive surface, the pressing section being guided and moved along the direction of substrate conveyance depending on movement of the follower roller.

The present invention provides the conveying device, wherein the upstream-side pressing mechanism includes a pair of adjoining link members that are provided in the drive link section of the link mechanism and have opposite directions of rotation, and wherein a belt-shaped pressing means made of an integral elastic member having belt shape is provided across the pair of adjoining link members.

The present invention provides the conveying device, wherein the upstream-side pressing mechanism includes a drive support section that is provided in the drive link section of the link mechanism, and a follower mechanism section driven by the drive support section, and wherein the follower mechanism section includes a follower section having a long-grooved sliding section capable of engagement and sliding with the drive support section, and a pressing section is connected to the follower section and the pressing section is guided and moved along the direction of substrate conveyance depending on movement of the drive support section in the long-grooved sliding section of the follower section.

The present invention provides the conveying device, wherein the upstream-side pressing mechanism is configured such that a plurality of driving magnets having different polarities is provided on the drive link section, a follower magnet having a single polarity is provided on the follower mechanism section, and the plurality of driving magnets and the follower magnet approach or separate from each other depending on relative positional relationship between the drive link section and the follower mechanism section.

The present invention provides a conveying device including an extensible link mechanism having a plurality of arms to which power from a drive source is transmitted; a mounting section for mounting an object to be conveyed, the mounting section being connected to an operating tip section of the link mechanism through a drive link section; an upstream-side pressing mechanism provided in an area of the mounting section on an upstream side in a direction of substrate conveyance, the upstream-side pressing mechanism making contact with a side portion of the object to be conveyed so as to press the object to be conveyed toward downstream side in the direction of substrate conveyance in accordance with operation of the drive link section of the link mechanism; and a downstream-side pressing mechanism provided in an area of the mounting section on a downstream side in the direction of substrate conveyance, the downstream-side pressing mechanism making contact with the side portion of the object to be conveyed so as to press the object to be conveyed toward the link mechanism lying on the upstream side in the direction of substrate conveyance in accordance with an operation of the drive link section of the link mechanism. The upstream-side pressing mechanism includes cam drive surfaces respectively provided on a pair of adjoining link members provided in the drive link section of the link mechanism, and a follower mechanism section having a pair of follower rollers that are capable of making contact with and following the pair of cam drive surfaces, respectively, and a pressing section that moves straight in the direction of substrate conveyance depending on movement of the pair of follower rollers. A moving distance of the pressing section of the follower mechanism section is set such that the pressing section of the follower mechanism section is not in contact with the side portion of the object to be conveyed when the link mechanism is extended and such that the pressing section of the follower mechanism section is in contact with the side portion of the object to be conveyed when the link mechanism is contracted; and the object to be conveyed is sandwiched and held from both sides in the direction of substrate conveyance by pressing of the upstream-side pressing mechanism and the downstream-side pressing mechanism.

The present invention provides the conveying device, the downstream-side pressing mechanism including a pair of drive members provided so as to move in the direction of substrate conveyance depending on movement of the follower mechanism section of the upstream-side pressing mechanism, cam drive surfaces being provided on respective one ends of the pair of drive members on the downstream side in the direction of substrate conveyance, and follower latch members having a gripping section capable of making contact with and following the respective cam drive surfaces of the pair of drive members. The follower latch members are configured such that each of the gripping sections rotates and moves upstream in the direction of substrate conveyance so as to erect from an oblique condition depending on the downstream movement of the pair of drive members in the direction of the substrate conveyance, and a moving distance of a pressing section of the follower latch member is set such that the gripping sections of the follower latch members is not in contact with the side portion of the object to be conveyed when the link mechanism is extended; and the follower latch members are also configured such that the gripping sections of the follower mechanism sections are in contact with the side portion of the object to be conveyed when the link mechanism is contracted.

The present invention also provides a vacuum apparatus including a vacuum chamber, and a conveying device including an extensible link mechanism having a plurality of arms to which power from a drive source is transmitted, a mounting section for mount in an object to be conveyed, the mounting section being connected to an operating tip section of the link mechanism through a drive link section, and a downstream-side pressing mechanism provided in an area of the mounting section on a downstream side in a direction of substrate conveyance. The downstream-side pressing mechanism makes contact with a side portion of the object to be conveyed so as to press the object to be conveyed toward the link mechanism in accordance with the operation of the drive link section of the link mechanism, the object to be conveyed being sandwiched and held from both sides in the direction of substrate conveyance by pressing of the downstream-side pressing mechanism; and the mounting section of the conveying device is configured to carry in and out of the vacuum chamber.

According to the present invention, the downstream-side pressing mechanism which makes contact with the side portion of the object to be conveyed so as to press the object to be conveyed toward the link mechanism in accordance with the operation of the link mechanism is provided in an area of the mounting section on the downstream side in the direction of substrate conveyance. The object to be conveyed is sandwiched and held from both sides in the direction of substrate conveyance by the pressing of the downstream-side pressing mechanism so as to hold mechanically. It is therefore possible to suppress a slide of the object to be conveyed over the top surface of the mounting section (in principle, eliminate the slide) for high speed conveyance of the object to be conveyed.

All the members including the pressing means may be made of metal, so that it is possible suppressing the slide of the object to be conveyed not only in an environment where the object to be conveyed and the ambience are relatively low in temperature, but also at high conveyance temperatures (for example, 300 to 500° C.) without thermal alteration or deformation.

Moreover, since the parts for gripping the object to be conveyed have no sliding portion, it is possible to reduce the generation of dust that may contaminate the object to be conveyed.

According to the present invention, when the upstream-side pressing mechanism, which makes contact with the side portion of the object to be conveyed so as to press the object to be conveyed in the direction of substrate conveyance is provided in an area of the mounting section on the upstream side in the direction of substrate conveyance, it is possible to simultaneously grip the object to be conveyed from both sides in the direction of substrate conveyance. It is thus possible to provide a conveyance device that will not cause a slide of the object to be conveyed nor generate dust.

According to the present invention, when the downstream-side pressing mechanism includes the drive section of a cam type and the downstream-side pressing section of a cam type to be driven by the drive section of cam type, a sliding portion of a cam mechanism can be arranged at the lower side of a substrate which is the object to be conveyed so that it is possible to prevent the surface of the substrate from the contamination of dust that occurs, for example, from the sliding portion.

Moreover, according to the present invention, when the downstream-side pressing mechanism includes the drive section of a link type and the downstream-side pressing section of a link type to be engaged with and driven by the drive section of a link type, the sliding portion of the link mechanism can be positioned away from a substrate which is the object to be conveyed. This can prevent the surface of the substrate from contamination with dust that occurs for example, from the sliding portion.

Moreover according to the present invention, if the device includes two downstream-side pressing sections, and the gripping sections provided on the respective downstream-side pressing sections are arranged to be line-symmetrical with respect to a straight line that extends in the direction of the substrate conveyance through the center axes of rotation of the first and second drive shafts, the substrate can be pressed and held (gripped) by the two gripping sections in a well-balanced manner.

Moreover, according to the present invention, if the upstream-side pressing mechanism includes the cam drive surface that is provided on the drive link section of the link mechanism, and the follower mechanism section that includes the pressing section having the follower roller in contact with and capable of following the cam drive surface and being guided and moved along the direction of the substrate conveyance due to the movement of the follower roller, the cam-and-roller based power transmission makes it possible to provide a small-sized conveying device with a simple configuration. Since the parts for gripping the object to be conveyed have no sliding portion, it is possible to reduce the generation of dust that may contaminate the object to be conveyed.

According to the present invention, if the upstream-side pressing mechanism includes the pair of adjoining link members which are provided in the drive link section of the link mechanism and have opposite directions of rotation, and the belt-shaped pressing means made of an integral elastic member having belt shape is laid across the pair of adjoining link members, there is no sliding portion in the vicinity of the area where the object to be conveyed is gripped, so that it is possible to minimize the generation of dust that may contaminate the object to be conveyed.

According to the present invention, if the upstream-side pressing mechanism includes the drive support section provided in the drive link section of the link mechanism and the follower mechanism section to be driven by the drive support section, and the follower mechanism section includes the follower section that has the long-grooved sliding section capable of engagement and sliding with the drive support section, and the pressing section that is connected to the follower section and is guided and moved along the direction of substrate conveyance due to the movement of the drive support section in the long-grooved sliding section of the follower section, the power transmission by a slide mechanism makes it possible to provide a small-sized conveying device with a simple configuration. Since the parts for gripping the object to be conveyed have no sliding portion, it is possible to reduce the generation of dust that may contaminate the object to be conveyed.

According to the present invention, if the upstream-side pressing mechanism is configured such that the drive link section includes the plurality of driving magnets having different polarities, the follower mechanism section includes the follower magnet having a single polarity, and each of the plurality of driving magnets and the follower magnet approach or separate from each other depending on the relative positional relationship between the drive link section and the follower mechanism section, it is possible to transmit the driving force from the drive link section to the following mechanism section without contact. It is thus possible to reduce the generation of dust that may contaminate the object to be conveyed.

### BRIEF DESCRIPTION OF THE DRAWINGS

FIG. 1 is a plan view schematically showing the general configuration of a conveying device according to the present invention.

FIG. 2(a) is a configuration diagram showing an example of a follower mechanism section of an upstream-side pressing mechanism according to the present invention; and FIG. 2(b) is a configuration diagram showing the upstream-side pressing mechanism in its entirety.

FIGS. 3(a) and 3(b) are diagrams explaining the principle of operation and configuration of the upstream-side pressing mechanism in detail.

FIG. 4 is a plan view showing the downstream-side pressing mechanism and the upstream-side pressing mechanism.

FIG. 5(a) is a plan view showing essential parts of the downstream-side pressing mechanism; and FIG. 5(b) is a partial sectional view showing essential parts of the downstream-side pressing mechanism.

FIG. 6(a) is a plan view showing essential parts of the downstream-side pressing mechanism; and FIG. 6(b) is a partial sectional view showing essential parts of the downstream-side pressing mechanism.

FIGS. 7(a) to 7(c) are explanatory diagrams showing the operation of the conveying device according to the present invention.

FIG. 8 is a plan view showing the upstream-side pressing mechanism and the downstream-side pressing mechanism according to another example of the present invention.

FIGS. 9(a) and 9(b) are plan views showing essential parts of the downstream-side pressing mechanism.

FIG. 10 is a diagram showing another example of the upstream-side pressing mechanism according to the present invention.

FIG. 11 is a partial sectional side view showing essential parts of another example of the upstream-side pressing mechanism.

FIG. 12 is a configuration diagram showing essential parts of yet another example of the upstream-side pressing mechanism.

FIG. 13 is a configuration diagram showing essential parts of yet another example of the upstream-side pressing mechanism.

FIGS. 14(a) and 14(b) are diagrams showing the configuration and operation of essential parts of yet another example of the upstream-side pressing mechanism.

FIG. 15(a) is a configuration diagram showing yet another example of the upstream-side pressing mechanism in its entirety, according to the present invention; and FIG. 15(b) is a sectional view taken along the lines A-A of FIG. 15(a).

FIG. 16 is a diagram explaining the principle of operation and configuration of the example in detail,

FIGS. 17(a) and 17(b) are diagrams showing the configuration and operation of yet another example of the upstream-side pressing mechanism according to the present invention.

FIGS. 18(a) and 18(b) are diagrams showing the configuration and operation of yet another example of the upstream-side pressing mechanism according to the present invention.

FIG. 19 is a schematic configuration diagram of a conveying device according to the conventional technology.

FIG. 20 is a schematic configuration diagram of essential carts of the conveying device according to the conventional technology.

### DETAILED DESCRIPTION OF THE INVENTION

Hereinafter, a preferred embodiment of the present invention will be described in detail with reference to the drawings.

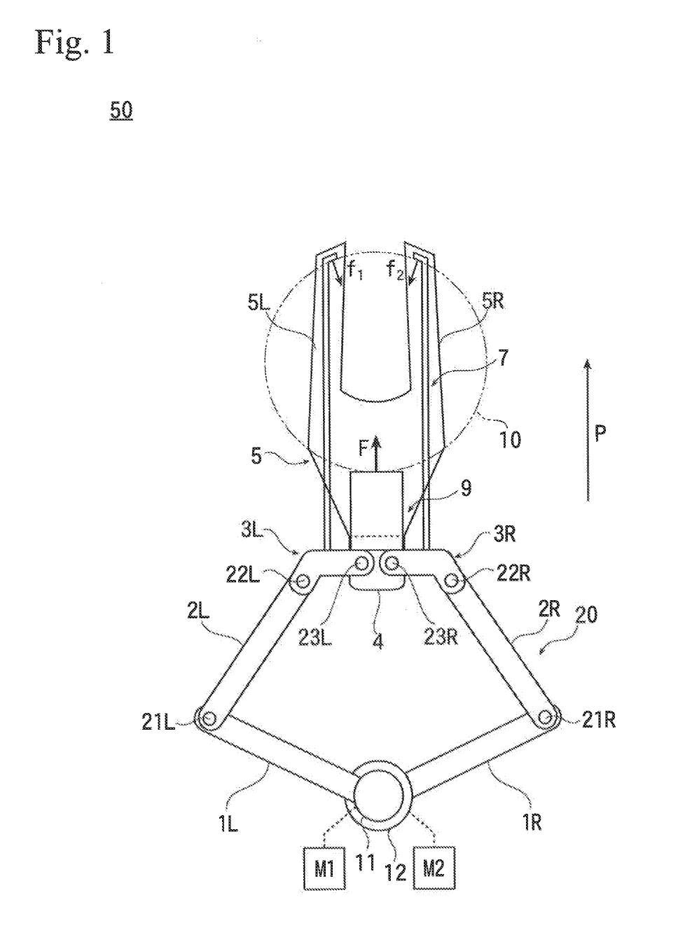

FIG. 1 is a plan view schematically showing the general configuration of a conveying device according to the present invention.

As shown in FIG. 1, the conveying device 50 according to the present invention is a so-called frog leg type, which conveys a substrate 10 as an object to be conveyed within a vacuum processing chamber, for example. The conveying device 50 has first and second drive shafts 11 and 12 for driving a link mechanism 20 to be described later and are concentrically arranged in a vertical direction.

These drive shafts 11 and 12 are configured such that clockwise or counterclockwise rotational power is transmitted thereto from independent first and second drive sources M1 and M2, respectively.

An end (base end) of a first left arm 1L is fixed to the first drive shaft 11; and an end (base end) of a first right arm 1R is fixed to the second drive shaft 12.

An end (base end) of a second left arm 2L is attached to the other end (top end) of the first left arm 1L so as to be horizontally rotatable about a spindle 21L.

An end (base end) of a second right arm 2R is attached to the other end (top end) of the first right arm 1R so as to be horizontally rotatable about a spindle 21R.

In the present embodiment, the first left arm 1L and the first right arm 1R are formed in a straight shape and configured to have the same span between pivot points.

The second left arm 2L is formed in a straight shape; and an end (base end) of a third left arm 3L is fixed to the other end (top end) with a fixing screw 22L.

The second right arm 2R is formed in a straight shape; and an end (base end) of a third right arm 3R is fixed to the other end (top end) with a fixing screw 22R.

Here, the third left arm 3L and the third right arm 3R, which constitute a drive link section, are formed in a generally “L” shape, and are arranged with the protruded portions of their respective bends toward the outside of the link.

The other end (top end) of the third left arm 3L is horizontally rotatably attached about a spindle 2 3L which is provided, for example, on the surface side of a power transmission mechanism 4 to be described later.

The other end (top end) of the third right arm 3R is horizontally rotatably attached about a spindle 23R which is provided, for example, on the surface side of the power transmission mechanism 4 to be described later.

The present embodiment is configured such that the span between the spindle 21L of the second left arm 2L and the spindle 231 of the third left arm 3L, and the span between the spindle 21R of the second right arm 2R and the spindle 23R of the third right arm 3R are the same distance.

The power transmission mechanism 4 has a pair of gears (not shown) which mesh with each other in a housing having a, for example, a rectangular slim box shape.

These gears have the same numbers of teeth, and their rotation shafts are fixed to the foregoing spindles 23L and 23R, respectively, whereby, the gears rotate in opposite directions at the same speed so as to function as an orientation control mechanism.

The spindles 23L and 23R are arranged close to each other in a direction orthogonal to the direction of substrate conveyance.

In the present invention, the arrangement of the spindles 23L and 23R is not particularly limited. So as to hold the object to be conveyed in a well-balanced manner, it is however preferred that the spindles 23L and 23R be arranged in positions that pass the center axis of rotation of the first and second drive shafts 11 and 12 and are orthogonal to the direction of substrate conveyance 21 (the direction of the arrow P).

A mounting section 5, called end effector is provided on the downstream side of the power transmission mechanism 4 in the direction of substrate conveyance.

The mounting section 5 has support members 5L and 5R which are provided at a predetermined distance from each other.

Meanwhile, in the present invention, a downstream-side pressing mechanism 7 for gripping the substrate 10 is provided at the ends of the support members 5L and 5R on the downstream side in the direction of substrate conveyance.

As discussed later, the downstream-side pressing mechanism 7 is configured such that right and left downstream-side pressing sections 70R and 70L are in contact with and respectively press side portions of the substrate 10 toward the link mechanism 20 (upstream side in the direction of substrate conveyance; shown by the reference symbols f1 and f2) in accordance with the operation of the third left arm 3L and the third right arm 3R which constitute the link mechanism 20 at the area of the mounting section 5 on the downstream side in the direction of substrate conveyance.

In the present invention, an upstream-side pressing mechanism 9 is provided in an area of the mounting section 5 on the upstream side in the direction of substrate conveyance.

As discussed later, the upstream-side pressing mechanism 9 is configured so as to make contact with a side portion of the substrate 10 to press the substrate 10 in the direction of substrate conveyance (shown by the reference symbol F) in accordance with the operation of the third left arm 3L and the third right arm 3R which constitute the link mechanism 20.

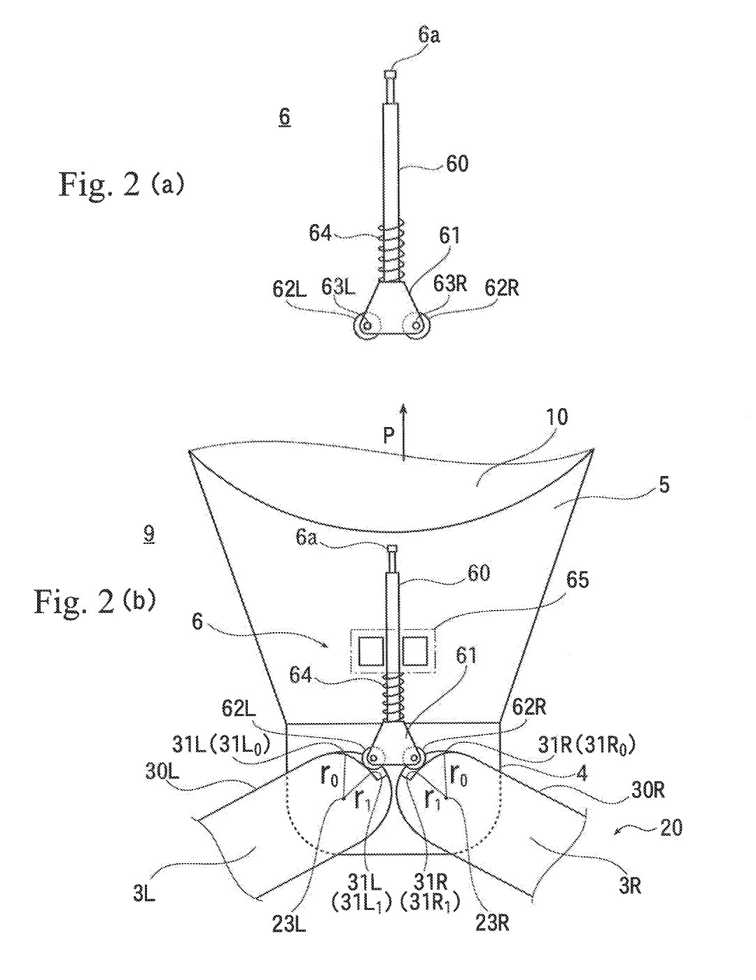

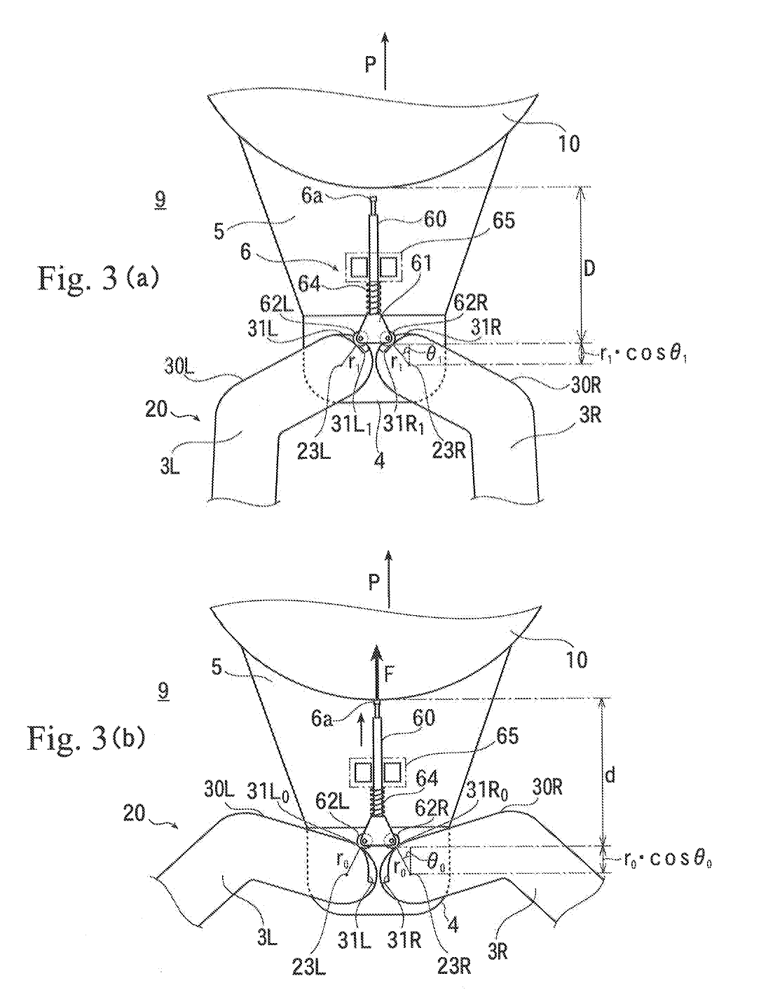

FIG. 2(a) is a configuration diagram showing an example of a follower mechanism section of the upstream-side pressing mechanism according to the present invention. FIG. 2(b) is a configuration diagram showing the entire upstream-side pressing mechanism. FIGS. 3(a) and 3(b) are diagrams explaining the principle of operation and con figuration of the upstream-side pressing mechanism in detail.

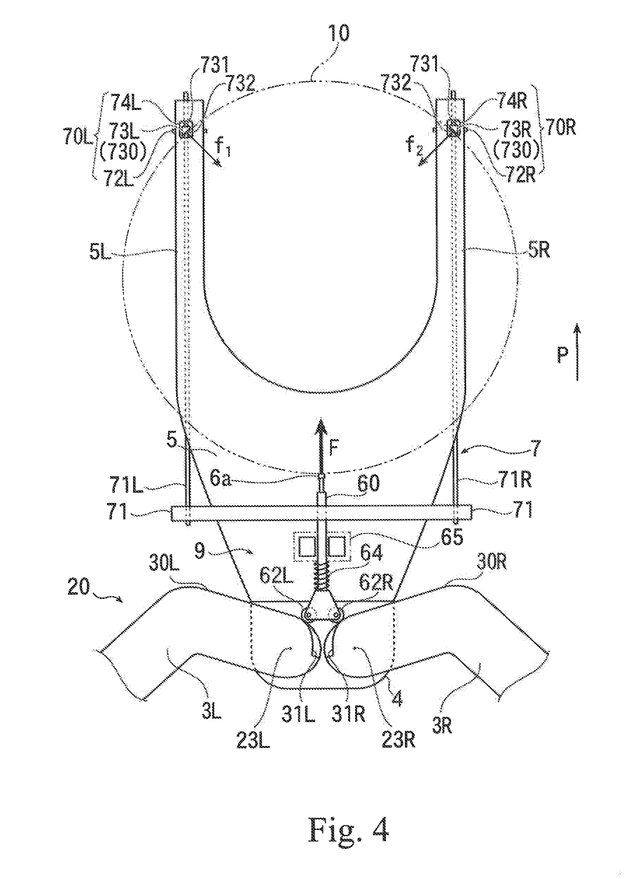

It should be noted that, in FIGS. 2(a), 2(b), 3(a), and 3(b), a base section 71 of the downstream-side pressing mechanism 7 is attached and fixed to a body section 60 of the follower mechanism section 6, as shown in FIG. 4, to be discussed later. For the sake of convenience, the description of the downstream-side pressing mechanism 7 will be omitted here.

As shown in FIG. 2(b), in the present example, each of the third left arm 3L and the third right arm 3R is formed to have a top end of semicircular shape. Arc-like cam drive surfaces 31L and 31R are provided on a part of the respective top ends on the downs cream side in the direction of substrate conveyance. The upstream-side pressing mechanism 9 is composed of the cam drive surfaces 31L and 31R of the third left arm 3L and the third right arm 3R and the follower mechanism section 6, as shown in FIG. 2a).

Here, the cam drive surfaces 31L and 31R of the third left arm 3L and the third right arm 3R are formed to have an arcuate shape convex to the downstream side in the direction of substrate conveyance, for example, by forming a step-like notch in the upper surfaces of the third left arm 3L and the third right arm 3R, respectively.

In the present example, the cam drive surfaces 31L and 31R of the third left arm 3L and the third right arm 3R are each configured such that the amount of displacement r1 on the top end side (the distance between the spindle 23L and an inner contact surface 31L1, the distance between the spindle 23R and an inner contact surface 31R1) is smaller than the amount of displacement r0 on the base end side (the distance between the spindle 23L and an outer contact surface 31L0, the distance between the spindle 23R and an outer contact surface 31R0) (r1<r0).

In the present example, the cam drive surfaces 31L and 31R of the third left arm 3L and the third right arm 3R are formed to be line-symmetrical with respect to a straight line that extends in the direction of substrate conveyance through the center axis of rotation of the first and second drive shafts 11 and 12.

On the other hand, the follower mechanism section 6 of the present example is made of metal members, preferably stainless steel or the like, and includes the body section 60 of a straight bar shape.

A support member 61 of, for example, trapezoidal shape is attached to one end of the body section 60 of the follower mechanism section 6. Follower rollers 62L and 62R having perfect circular shape and the same diameter, for example, are provided on respective ends of the bottom of the trapezoidal support member 61.

The follower rollers 62L and 62R are arranged, for example, so as to be line-symmetrical with respect to a straight line in the direction of the extension of the body section 60, and are configured to rotate about spindles 63L and 63R which are in a direction orthogonal to a plane that includes the body section 60.

A pressing section 6a having, for example, protruding shape (here, pin shape) is attached to the other end of the body section 60 of the follower mechanism section 6. The top end of the pressing section 6a may be coated with a heat resistant resin material (such as, PTFE (polytetrafluoroethylene resin)) in order to avoid dust generation.

A compression coil spring 64 is attached to around the body section 60, between the mid-section of the body section 60 of the follower mechanism section 6 and the support member 61 described above. The top portion of the compression coil spring 64 is fixed to the support member 61.

In the present example, as shown in FIG. 2(b), the follower rollers 62L and 62R of the follower mechanism section 6 are placed into contact with the cam drive surfaces 31L and 31R of the third left arm 3L and the third right arm 3R, respectively. In such a state, the body section 60 of the follower mechanism section 6 is guided, for example, by a guide member 65 which is provided on the surface of the mounting section 5, so that the body section 60 moves straight in the direction of substrate conveyance through the center axis sine of rotation of the first and second drive shafts 11 and 12.

In such a case, the compression coil spring 64 attached to the body section 60 of the follower mechanism section 6 makes contact with and is latched by the guide member 65 at the end portion of the compression coil spring 64 on the side of the pressing section 6a. By the elastic force, the follower rollers 62L and 62R of the follower mechanism section 6 are pressed against the cam drive surfaces 31L and 31R of the third left arm 31 and the third right arm 3R.

Next, the principle of operation and configuration of the upstream-side pressing mechanism will be described in detail with reference to FIGS. 3(a) and 3(b).

In the present example, when the link mechanism 20 is extended, as shown in FIG. 3(a), the angle formed between an attachment surface 30L of the third left arm 3L and an attachment surface 30R of the third right arm 3R is set to, for example, greater than 180 degrees.

As shown in FIG. 3(b), when the link mechanism 20 is contracted, the angle formed between the attachment surface 30 of the third left arm 3L and the attachment surface 30R of the third right arm 3R is set to, for example, smaller than 180 degrees, for example.

In such a configuration, when the link mechanism 20 is extended, as shown FIG. 3(a), the length of the follower mechanism section 6 (here, the distance between the top end of the pressing section 6a and the inner contact surfaces 31L1 and 31R1 of the cam drive surfaces 31L and 31R to the follower rollers 62L and 62R) is set such that when the link mechanism 20 is extended, the pressing section 6a on the downstream side of the follower mechanism section 6 in the direction of substrate conveyance does not make contact with the side portion of the substrate 10 to be conveyed. In addition, the angles of the attachment surfaces 30L and 30R of the third left arm 3L and the third right arm 3R and the amount of displacement r1 of the cam drive surfaces 31L and 31R are set to determine the distance between the inner contact surfaces 31L and 31R1 to the follower rollers 62L and 62R, and the side portion of the substrate as distance D.

On the other hand, when the link mechanism 20 is contracted, as shown in FIG. 3(b), the angle formed between the attachment surface 30L of the third left arm 3L and the attachment surface 30R of the third right arm 3R is smaller than 180 degrees; and the follower rollers 62L and 62R of the follower mechanism section 6 move along the cam drive surfaces 31L and 31R of the third left arm 3L and the third right arm 3S toward the outer contact surfaces 31L0 and 31R0, respectively. As a result, the distance between the spindles 23L and 23R of the third left arm 3L and the third right arm 3R and the respective cam drive surfaces 31L and 31R increase (r0>r1).

In such a case, according to the present example, angles between straight lines that extend from the contact areas of respective cam drive surfaces 31L and 31R to the follower rollers 62L and 62R of the follower mechanism section 6, and the respective spindles 23L and 23R form a smaller angle with respect to the direction of substrate conveyance when the link mechanism 20 is contracted than when the link mechanism 20 is extended (θ0<θ1). Thus, due to the third left arm 3L and the third right arm 3R being rotated to the contracting directions, the follower mechanism section 6 therefore moves downstream side in the direction of substrate conveyance, thereby, decreasing the distance from the contact ends of the follower rollers 62L and 62R to the side portion of the substrate 10 to be conveyed (r0·cos θ0>r1·cos θ1, i.e., d<D).

As a result, the portion of the follower mechanism section 6 on the downstream side in the direction of substrate conveyance (pressing section 6a) makes contact with the side portion of the substrate 10 to be conveyed, and the side portion of the substrate 10 undergoes force F in the direction of substrate conveyance.

In the present example, because the foregoing operation brings the portion of the compression coil spring 64 on the downstream side in the direction of conveyance into contact with the guide member 65 for compression, the follower rollers 62L and 62R of the follower mechanism section 6 are pressed against and put into close contact with the cam drive surfaces 31L and 31R of the third left arm 31 and the third right arm 3R by the elastic force of the compression coil spring 64. Consequently, the follower mechanism section 6 moves toward the downstream side in the direction of the substrate conveyance along the guide member 65 with reliability and high precision.

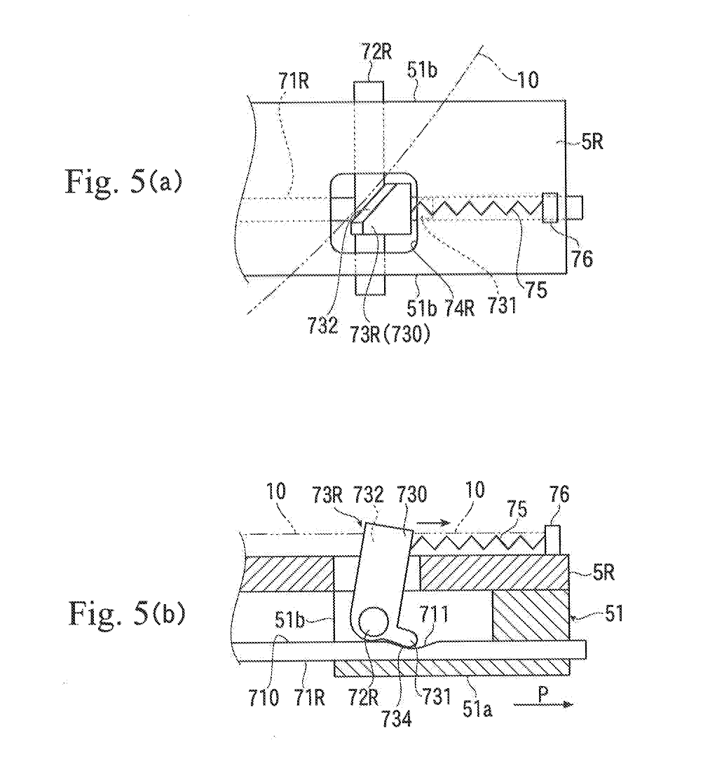

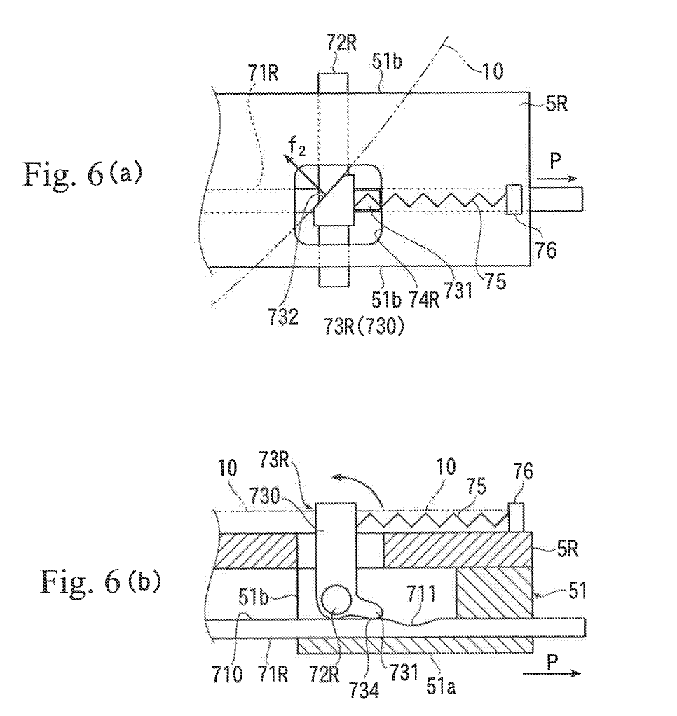

FIG. 4 is a plan view showing the downstream-side pressing mechanism and the upstream-side pressing mechanism according to the present example. FIG. 5(a) is a plan view showing the essential parts of the downstream-side pressing mechanism. FIG. 5(b) is a partial sectional view showing the essential parts of the downstream-side pressing mechanism. FIG. 6(a) is a plan view showing the essential arts of the downstream-side pressing mechanism. FIG. 6(b) is a partial sectional view showing the essential parts of the downstream-side pressing mechanism.

As shown in FIG. 4, according to the present example, the downstream-side pressing mechanism 7, which has a left downstream-side pressing section 70L and a right downstream-side pressing section 70R, is provided in an area of the mounting section 5 on the downstream side in the direction of substrate conveyance.

Here, the downstream-side pressing mechanism 7 has the base section 71 having a straight bar shape. The base section 71 is attached and fixed to the body section 60 of the foregoing follower mechanism section 6, and extends in a direction orthogonal to the direction of substrate conveyance (the direction of the arrow P).

The base section 71 has almost the same length as the distance between the support members 5L and 5R of the mounting section 5. A left drive member 71L having a straight bar shape extending in the direction of substrate conveyance is attached and fixed to the left support member 5L. A right drive member 71R having a straight bar shape extending in the direction of substrate conveyance is attached and fixed to the right support member 5R.

In the present example, the left drive member 7L and the right drive member 71R are located along and under the support members 5L and 5R, respectively.

The left drive member 71L and the right drive member 71R are arranged to be line-symmetrical with respect to a straight line that extends in the direction of substrate conveyance through the center axis of rotation of the foregoing first and second drive shafts 11 and 12.

The left downstream-side pressing section 70L and the right downstream-side pressing section 70R are provided the top portions of the left and right support members 5L and 5R of the mounting section 5. In the present example, the base section 71, the left drive member 71L, and the right drive member 71R, as described above, constitute a drive mechanism, which is configured to drive both the left downstream-side pressing section 70L and the right downstream-side pressing section 70R due to the operation of the link mechanism 20.

Here, the left downstream-side pressing section 70L and the right downstream-side pressing section 70R are configured to operate by the same mechanism, and are arranged to be line-symmetrical with respect to a straight line that extends in the direction of substrate conveyance through the center axis of rotation of the first and second drive shafts 11 and 12.

Referring to FIGS. 4, 5(a), 5(b), 6(a), and 6(b), the configuration and operation of the downstream-side pressing mechanism according to the present invention will now be described by making reference to the right downstream-side pressing section 70R when necessary.

As shown in FIGS. 5(a) and 5(b), the right downstream-side pressing section 70R of the present example has a holding section 51 having, for example, a box shape which is attached to a lower side of the support member 5R.

The right drive member 71R described above is horizontally supported on a bottom portion 51a of the holding section 51.

A spindle 72R which extends at right angles to the direction of substrate conveyance and is horizontally situated, is rotatably supported by side wall sections 51b which are provided on both sides of the holding section 51.

A right clamp latch member 73R which constitutes the right downstream-side pressing section 70R, is attached and fixed to the spindle 72R.

The right clamp latch member 73R is formed in a generally “L” shape. The right clamp latch member 73R is composed of a gripping section 730 which extends vertically upward, and a cam follower section 731 which extends to the downstream side of the spindle 72R in the direction of substrate conveyance.

The gripping section 730 of the right clamp latch member 73P is configured such that its top portion protrudes from an opening 74R which is provided in the support member 5R.

The gripping section 730 is formed to have a length (i.e., span greater than the length of the cam follower section 731), and is configured such that its top portion protrudes from the opening 74R provided in the support member 5R.

In the present example, as shown in FIG. 5(b), an end of an elastic member (such as, a tension coil spring 75) is attached to a portion of the gripping section 730 of the right clamp latch member 73R on the downstream side in the direction of substrate conveyance. The other end of the tension coil spring 75 is attached to an attachment member 76, which is positioned on the downstream side of the support member 5R in the direction of substrate conveyance.

As shown in FIG. 5(b), the tension coil spring 75 is configured to pull the gripping section 730 of the right clamp latch member 73R to the downstream side in the direction of substrate conveyance.

The gripping section 730 of the right clamp latch member 73R has a gripping surface 732 having, for example, a flat shape which is tilted by a predetermined angle (for example, 45 degrees or so inward of the substrate 10 to be conveyed with respect to the direction or substrate conveyance.

The gripping surface 732 of the right clamp latch member 73R may be coated with a heat resistant resin material (such as, PTFE) in order to avoid generating dust.

The cam follower section 731 of the right clamp latch member 73R is formed slightly downward with respect to the spindle 72R. The cam follower section 731 is configured such that the portion immediately below the spindle 72R and a bottom surface 734 of the cam follower section 731 make contact with a top surface 710 (and a cam drive surface 711 to be described below) of the drive member 71R.

The top end of the cam follower section 731 is formed in a round shape.

In the present example, the cam drive surface 711 is formed in a concave shape, the shape of a concave surface that fits to the bottom surface 734 of the cam follower section 731 of the right clamp latch member 73R.

The contact area between the cam follower section 731 of the right clamp latch member 73R and the top surface 710 of the drive member 71R can be coated with a heat resistant resin material (such as, PTFE) in order to avoid generating dust.

In the meantime, the left downstream-side pressing section 70L has the same configuration as that of the right downstream-side pressing section 70R described above. As shown in FIG. 4, the left downstream-side pressing section 70L includes a spindle 72L, a left clamp latch member 73L, and an opening 74L which are arranged to be line-symmetrical with respect to a straight line that extends in the direction of substrate conveyance. The left clamp latch member 73L includes a gripping section 730, a cam follower section 731, and a gripping surface 732.

The drive member 71L has the same configuration as that of the foregoing drive member 71R. The top surface of the drive member 71L includes a not-shown cam drive surface 711 of a convex surface shape that fits to the bottom surface 734 of the cam follower section 731 of the left clamp latch member 73L.

Next, the principle of operation and configuration of the downstream-side pressing mechanism will be described in detail in reference to FIGS. 4, 5(a), 5(b), 6(a), and 6(b).

In the present example, as described above, the length of the follower mechanism section 6 is set such that the pressing section 6a on the downstream side of the follower mechanism section 6 in the direction of substrate conveyance does not make contact with the side portion of the substrate 10 to be conveyed when the link mechanism 20 is extended.

In such a state, the base section 71, fixed to the body section 60 of the follower mechanism section 6, lies in a predetermined position on the upstream side in the direction of substrate conveyance. Consequently, the left drive member 71L and the right drive member 71R are also located in predetermined positions on the upstream side in the direction of substrate conveyance.

In such a positional relationship, for example, as shown in FIGS. 5(a) and 5(b), the length of the right drive member 71R, the length of the cam follower section 731 of the right clamp latch member 73R, and the length, position, and shape of the cam drive surface 711 of the right drive member 71R are set so that the bottom area of the cam drive surface 711 provided in the right drive member 7R and the cam follower section 731 of the right clamp latch member 73R lie in overlapping positions in the direction of substrate conveyance.

In such a state, the gripping section 730 of the right clamp latch member 73R is pulled by the tension coil spring in the direction of substrate conveyance, so that the gripping section 730 of the right clamp latch member 73R is thus rotated about the spindle 72R so as to tilt in the direction of substrate conveyance, thereby, pressing the cam follower section 731 of the right clamp latch member 73R against the bottom area of the cam drive surface 711 of the right drive member 71R, and the cam follower section 731 of the right clam latch member 73R comes into contact with the bottom area of the cam drive surface 711 of the right drive member 71R to be rest state.

As shown in FIG. 5(a), the position of the spindle 72R, the length and shape of the gripping section 730 of the right clamp latch member 73R, and the position and shape of the gripping surface 732 are set such that the gripping surface 732 of the right clamp latch member 73R in such a state is positioned away from the rim of the substrate 10.

When the third left arm 3L and the third right arm 3R in such a state are rotated in the directions of contracting the link mechanism 20, the body section 60 of the follower mechanism section 6 moves in the direction of substrate conveyance (the direction of the arrow P) along with the base section 71, the left drive member 71L, and the right drive member 71R.

Consequently, as shown in FIGS. 6(a) and 6(b), the cam follower section 731 of the right clamp latch member 73R comes out of the cam drive surface 711 of the right drive member 71R, and the bottom surface 734 of the cam follower section 731 makes contact with the top surface 710 of the drive member 71R, thereby gripping section 730 of the right clamp latch member 73R is rotated about the spindle 72R in the direction opposite to the direction of substrate conveyance (i.e., in the erecting direction).

In the present example, the position of the spindle 72R, the length and shape of the gripping section 730 of the right clamp latch member 73R, and the position and shape of the gripping surface 732 discussed above are set such that the gripping surface 732 of the right clamp latch member 73R makes contact with the rim of the substrate 10 that is pressed and moved by the pressing section 6a of the follower mechanism section 6 in the direction of substrate conveyance, as shown in FIG. 6(a), when the link mechanism 20 is contracted, as shown in FIG. 4.

In this state, for the left downstream-side pressing section 70L, similar to the right downstream-side pressing section 70R, the position of the spindle 72L, the length and shape of the gripping section 730 of the left clamp latch member 73L, and the position and shape of the gripping surface 732 are also set with respect to the cam drive surface 711 of the drive member 71 such that the gripping surface 732 of the left clamp latch member 73L makes contact with the rim of the substrate 10.

In the present invention, it is preferred, but not particularly limited, for the moving distances (strokes) of the gripping section 730 of the left clamp latch member 73L and the gripping section of 730 of the right clamp latch member 73R to be set to smaller than the moving distance of the left drive member 71L and the right drive member 71R; i.e., the moving distance of the follower mechanism section 6.

According to the present example having such a configuration, when the link mechanism 20 is contracted, as shown in FIG. 4, by a function of the force F in the direction of substrate conveyance from the pressing section 6a of the follower mechanism section 6, and also by functions of the forces f1 and f2 in the directions inward the substrate 10 from the left clamp latch member 73L of the left downstream-side pressing section 70L and the right clamp latch member 73R of the right downstream-side pressing section 70R to the link mechanism 20, the substrate 10 is subjected to the pressing forces from the upstream and downstream sides in the direction of substrate conveyance, whereby the substrate 10 is reliably held (gripped) on the mounting section 5.

With the link mechanism 20 in such a contracted state, the first left arm 1L and the first right arm 1R can be rotated in the same direction to make a turn while holding the substrate 10.

The timing, when the pressing section 6a of the follower mechanism section 6, the gripping surface 732 of the left clamp latch member 73L and the gripping surface 732 of the right clamp latch member 73R come into contact with the rim of the substrate 10, may be simultaneous with when the in k mechanism 20 is fully contracted, or may be before (immediately before) the link mechanism 20 is fully contracted. The timing may be appropriately changed depending on the size, arrangement, and configuration of the conveying device and the vacuum device to which the present invention is applied.

So as to grip the substrate 10 with high precision, a preferred configuration is for the pressing section 6a of the follower mechanism section 6 to make contact with the rim of the substrate 10 before the gripping surface 732 of the left clamp latch member 73L and for the gripping surface 732 of the right clamp latch member 73R to make contact with the rim of the substrate 10.

In particular, in the present example, the left downstream-side pressing section 70L (the gripping surface 732 of the left clamp latch member 73L) and the right downstream-side pressing section 70R (the gripping surface 732 of the right clamp latch member 73R) are arranged to be line-symmetrical with respect to a straight line that extends in the direction of substrate conveyance through the center axis of rotation of the first and second drive shafts 11 and 12. It is therefore possible to press and hold (grip) the substrate 10 in a well-balanced manner.

Moreover, in the present example, because the moving distances of the gripping section 730 of the left clamp latch member 73L and the gripping section 730 of the right clamp latch member 73R are set to be smaller than the moving distance of the follower mechanism section 6 in the direction of substrate conveyance. The timing and time at which the gripping surface 732 of the left clamp latch member 73L and the gripping surface 732 of the right clamp latch member 73R press the substrate 10 can be set, within a predetermined range with respect to the pressing timing of the pressing section 6a of the follower mechanism section 6. The substrate 10 can thus be gripped with high precision.

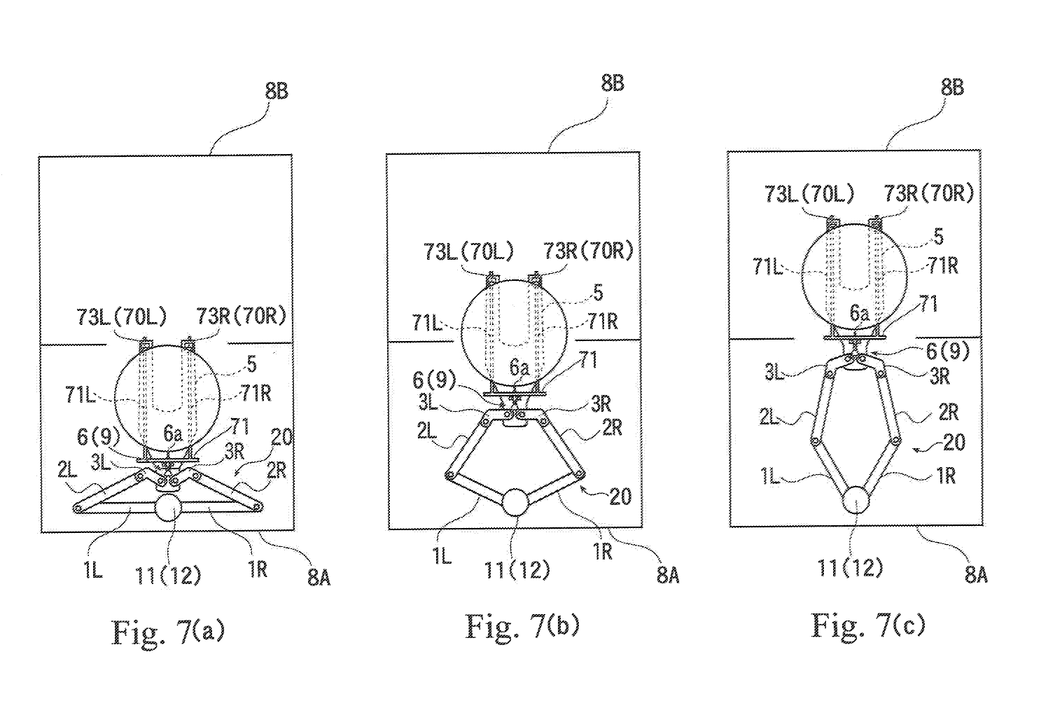

FIGS. 7(a) to 7(c) are explanatory diagrams showing the operation of the conveying device according to the present example.

Here, a description will be given of an example where the substrate 10 is carried from a conveyance chamber 8A into a process chamber 8B. It should be appreciated that the conveyance chamber 8A and the process chamber 8B are connected to a not-shown vacuum evacuation system. A not-shown gate valve is connected between the conveyance chamber 8A and the process chamber 8B. After the gate valve is opened, carry-in and carry-out operations are performed.

Initially, as shown in FIG. 7(a), the link mechanism 20 is contracted to hold the substrate 10 as described above, and the top end of the mounting section 5 is directed toward the process chamber 8B.

In such a state, as described above, the substrate 10 undergoes force from the pressing section 6a of the follower mechanism section 6 in the direction of substrate conveyance, and also forces in the directions from the left clamp latch member 73L of the left downstream-side pressing section 70L and the right clamp latch member 73R of the right downstream-side pressing section 70R to the link mechanism 20 through the base section 71, the left drive member 71L, and the right drive member 71R due to the power from the follower mechanism section 6. The substrate 10 is thereby gripped on the mounting section 5.

In that state, the first left arm 1L is rotated in a clockwise direction and the first right arm 1R is rotated in a counterclockwise direction to start the extending operation of the link mechanism 20. As shown in FIG. 7(b), the substrate 10 moves straight toward the process chamber 8B.

The extending operation of the link mechanism 20 is further continued to carry the substrate 10 into the process chamber 8B, as shown in FIG. 7(c).

In such a state, as described above, the pressing section 6a of the follower mechanism section 6 is not in contact with the side portion of the substrate 10, and the left clamp latch member 73L of the left downstream-side pressing section 70L and the right clamp latch member 73R of the right downstream-side pressing section 70R are not in contact with the side portion of the substrate 10. The substrate 10 can thus be supported and lifted by a lifting mechanism (not shown) which is installed in the processing chamber 8B, whereby the substrate 10 is detached from the mounting section 5 of the conveying device 50.

It should be noted that the timing to release the contact between the pressing section 6a of the follower mechanism section 6 to the side portion of the substrate 10 and the contact of the left clamp latch member 73L of the left downstream-side pressing section 70L and the right clamp latch member 73R of the right downstream-side pressing section 70R to the side portion of the substrate 10 may be simultaneous with when the link mechanism 20 is fully extended, or may be before (immediately before) the link mechanism 20 is fully extended. The timing can be appropriately changed depending on the size, arrangement, and configuration of the conveying device and the vacuum device to which the present invention is applied.

Subsequently, the first left arm 1L is rotated counterclockwise direction and the first right arm 1R is rotated clockwise direction to perform the contracting operation of the link mechanism 20, whereby the mounting section 5 can be moved back into the conveyance chamber 8A.

As discussed above, according to the present example, the downstream-side pressing mechanism 7, which has the left downstream-side pressing section 70L and the right downstream-side pressing section 70R is provided at the top portions of the left and right support members 5L and 5R of the mounting section 5. In addition, the upstream-side pressing mechanism 9, which operates by a cam mechanism is provided on the operating tip section of the link mechanism 20, so that the left clamp latch member 73L, the right clamp latch member 73R, and the pressing section 6a of the follower mechanism section 6 then sandwich and mechanically hold the substrate 10 from both sides in the direction of substrate conveyance. Thus, it is possible to suppress a slide of the substrate over the top surface of the mounting section 5 (in principle, eliminate the slide when the substrate 10 is simultaneously gripped from both sides) for achieving high speed conveyance of the substrate 10.

Since the members including the left downstream-side pressing section 70L, the right downstream-side pressing section 70R, and the follower mechanism section 6 are all made of metal, it is possible to suppress the slide of the substrate 10 not only in an environment where the object to be conveyed and the ambience are relatively low in temperature, but also at high conveyance temperatures (for example, 300 to 500° C.) without thermal alteration or deformation.

The left clamp latch member 73L, the right clamp latch member 73R, and the pressing section 6a of the follower mechanism 6 are members of protruding shape, and have no sliding portion at the areas for gripping the substrate 10. The substrate 10 experiences little sliding, as well. It is therefore possible to reduce the generation of dust that may contaminate the substrate 10.

Moreover, according to the present embodiment, the sliding portions of the cam mechanism are located under the substrate 10. Such a structural arrangement can prevent the surface of the substrate from contamination by dust generated by the sliding portions.

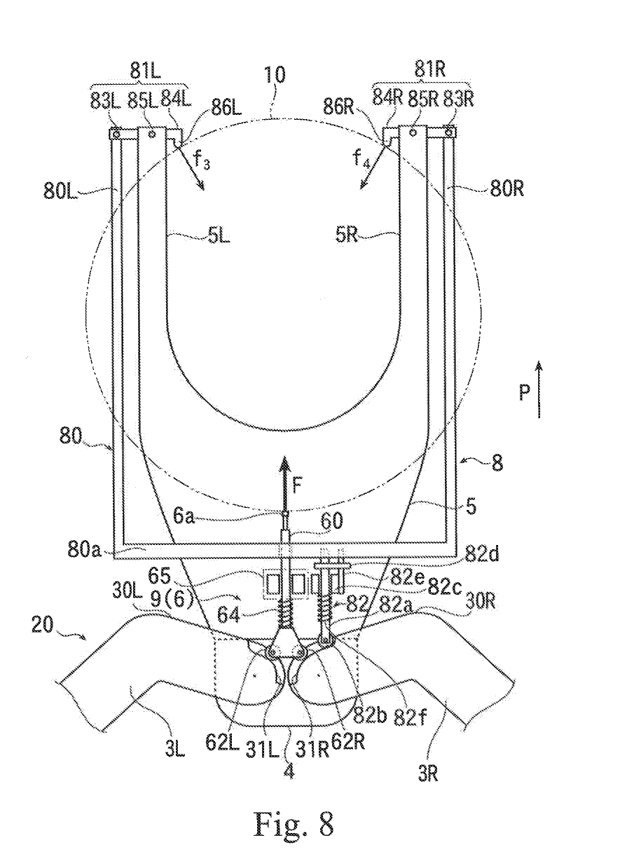

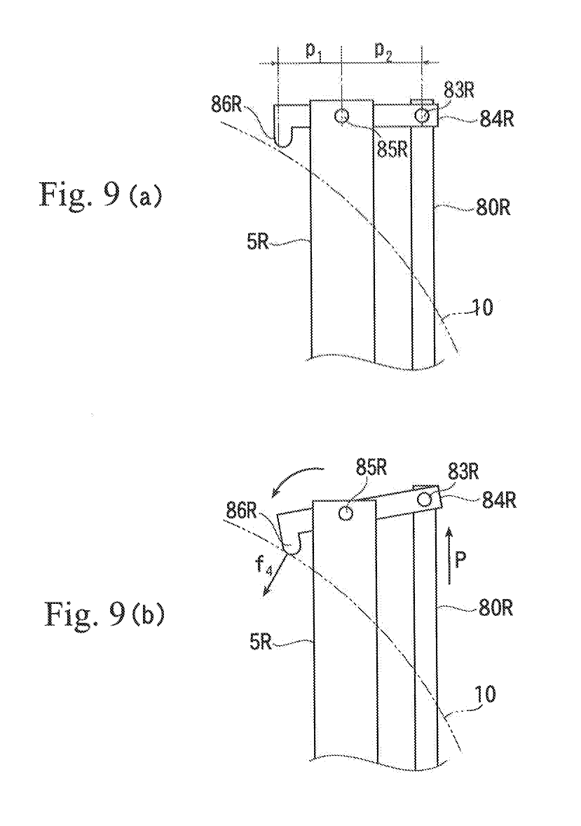

FIGS. 8, 9(a), and 9(b) show another example of the present invention. FIG. 8 is a plan view showing an upstream-side pressing mechanism and a downstream-side pressing mechanism. FIGS. 9(a) and 9(b) are plan views showing essential parts of the downstream-side pressing mechanism. Parts corresponding to those of the foregoing example will hereinafter be designated by identical reference numerals, and a detailed description thereof will be omitted.

As shown in FIG. 8, the downstream-side pressing mechanism 8 of the present example includes downstream-side pressing sections 81L and 81R to be described later, which are pressing mechanisms of a link type, and are provided on the top portions of the support members 5L and 5R of the mounting section 5, respectively. A drive member 80 for driving the downstream-side pressing sections 81L and 81R is also provided.

The drive member 80 is made of a generally “U” shaped member. The drive member 80 is composed of a base section 80a of straight bar shape, and a left drive section 80L and a right drive section 80R of a straight bar shape, which extend from respective ends of the base section 80a in a direction orthogonal to the base section 80a.

In the present example, the drive member 80 is arranged with the base section 80a orthogonal to the direction of substrate conveyance, and is configured such that the body section 60 of the follower mechanism section 6 penetrates through the base section 80a. The body section 60 of the follower mechanism section 6 and the drive member 80 are thereby arranged and configured such that they can relatively move in the direction of substrate conveyance and in the opposite direction.

The length of the base section 80a of the drive member 80 is set to be greater than the pitch between the support members 5L and 5R of the mounting section 5. When the drive member 80 is mounted on the conveying device 50, the left drive section 80L and the right drive section 80R are therefore located outside the support members 5L and 5R, respectively.

The left drive section 80L and the right drive section 80R of the drive member 80 are arranged to be line-symmetrical with respect to a straight line that extends in the direction of substrate conveyance through the center axis of rotation of the first and second drive shafts 11 and 12.

The drive member 80 is able to receive force from the third right arm 3R of the link mechanism 20 through a power transmission mechanism 82, as described below.

The power transmission mechanism 82 has a body section 82a having straight bar shape, and one of the ends of the body section 82a is orthogonally attached and fixed to the base section 80a of the foregoing drive section 80.

A follower roller 82b having perfect circular shape is horizontally rotatably supported at the other end of the body section 82a of the power transmission mechanism 82.

The third right arm 3R has a cam drive surface 31R which is formed from the too end toward the rear end of the third right arm 3R and has a length greater than in the example shown in FIG. 4.

The power transmission mechanism 82 is adjacently provided on the right side of the follower mechanism section 6. With the follower roller 82b in contact with the cam drive surface 31R, the body section 82a of the power transmission mechanism 82 is guided by a guide member 82c which is provided, for example, on the surface of the mounting section 5 so that the body section 82a moves straight in the direction of substrate conveyance or in the opposite direction.

In the present example, an attachment member 82d is fixed near the end of the body section 82a of the power transmission mechanism 82 in the direction of substrate conveyance. A fixing pin 82e having bar shape is attached to the attachment member 82d. An end of the fixing pin 82e is attached and fixed to the base section 80a of the drive member 80; and the other end of the fixing pin 82e is fixed to, for example, the guide member 82c. Such a configuration is employed to prevent rotation of the body section 82a of the power transmission mechanism 82 and the base section 80a of the drive member 80.

An end of a left link member 84L, as later described, is supported by the top end of the left drive section 80L of the drive member 80 so as to be horizontally rotatable about a spindle 83L. An end of a right link member 84R, as later described, is supported by the top end of the right drive section 80R of the drive member 80 so as to be horizontally rotatable about a spindle 83R.

The body section 82a is provided with a coil spring 82f, for example. One of the ends of the coil spring 82f is fixed to the body section 82a; and the other end is in contact with the guide member 82c. The coil spring 82f applies force to the body section 82a in the direction of substrate conveyance, whereby the gripping of the substrate 10 by gripping sections 86L and 86R, as later described, is released when the link mechanism 20 is extended.

The left link member 84L and the right link member 84R are made of members of the same generally “L” shape. The gripping sections 866L and 86R having, for example, rounded shape are provided on the top ends where they are not supported by the left drive section 80L or the right drive section 80R of the drive member 80, so as to extend in a direction orthogonal to the body portions.

The left link member 84L and the right link member 84R are supported at their respective midsections so as to be horizontally rotatable about spindles 85L and 85R which are provided on the top ends of the support members 5L and 5R of the mounting section 5, respectively. The left link member 84L and the right link member 84R are arranged with their respective gripping sections 86L and 86R in the direction opposite to the direction of substrate conveyance.

With such a structural arrangement, the gripping sections 86L and 86R of the left downstream-side pressing section 81L and the right downstream-side pressing section 81R are arranged to be line-symmetrical with respect to a straight line that extends in the direction of substrate conveyance through the center axis of rotation of the first and second drive shafts 11 and 12.

The portions of the gripping sections 86L and 86R, where contact is made with the rim of the substrate 10, can be coated with a heat resistant resin material (such as, PTFE) in order to avoid dust generation.

Next, the principle of operation and structural arrangement of the present example will be described in detail in reference to FIGS. 8, 9(a), and 9(b).

In the present example, the left downstream-side pressing section 81L and the right downstream-side pressing section 81R are configured to operate by the same mechanism. Hereinafter, the configuration and operation of the downstream-side pressing section of a link type according to the present invention will be described by referring to the right downstream-side pressing section 81R.

In the present example, similar to the example shown in FIG. 4, the length of the follower mechanism section 6 is set such that the pressing section 6a on the downstream side of the follower mechanism section 6 in the direction of substrate conveyance does not make contact with the side portion of the substrate 10 to be conveyed when the link mechanism 20 is extended.

When the link mechanism 20 contracts, the follower mechanism section 6 moves to a downstream side in the direction of substrate conveyance so that the pressing section 6a of the follower mechanism section 6 comes into contact with the side portion of the substrate 10 to be conveyed.

The power transmission mechanism 82 of the present example is configured to move with the follower mechanism section 6 in the same direction.

More specifically, as seen in FIG. 9(a), which shows an example with the right link member 84R, the shape of she third cam drive surface 31R of the third right arm, the lengths of the follower roller 82b and the body section 82a of the power transmission mechanism 82, the lengths of the base section 80a and the right drive section 80R of the drive member 80, the length of the right link member 84R (gripping section 86R), and the positions of the spindles 83R and 85R are each set such that the gripping section 86R does not make contact with the rim of the base section 10 when the link mechanism is extended.

For the left link member 84L, the lengths of the base section 80a and the left drive section 80L of the drive member 80, the length of the left link member 84L (gripping section 86L), and the positions of the spindles 83L and 85L are each set such that the gripping section 86L does not make contact with the rim of the base section 10.

In the present invention, it is preferred, but not particularly limited thereto, that the pitch P1 between the contact area of the gripping section 86R with the substrate 10 and the spindle 85R of the support member 5R is smaller than the pitch P2 between the spindle 85R of the support member 5R and the spindle 83R of the right drive section 80R as seen in FIG. 9(a), which shows an example for the right link member 84R.

For the left link member 84L, although not shown, the pitch between the contact area of the gripping section 86L with the substrate and the spindle 85L of the support member 5L may be smaller than the pitch between the spindle 85L of the support member 5L and the spindle 83L of the right drive section 80L.

With such a configuration, the moving distances of the gripping section 86L of the left link member 84L and the gripping section 86R of the right link member 84R can be set to be smaller than the moving distance of the follower mechanism section 6 in the direction of substrate conveyance.

In the present example, when third left arm 3L and the third right arm 3R are rotated in the directions of contracting the link mechanism 20 from the state where the link mechanism 20 is extended, the body section 60 of the follower mechanism section 6 moves in the direction of substrate conveyance. In the meantime, the force from the cam drive surface 31R of the third right arm 3R is transmitted to the base section 80a of the drive member 80 through the power transmission mechanism 82, whereby the drive member 80 is moved in the direction of substrate conveyance (the direction of the arrow P).

As a result, the left link member 84L and the right link member 84R rotate about the spindles 85L and 85R so that the gripping sections 86L and 86R move in the direction opposite to the direction of substrate conveyance (see, FIG. 9(b)).

In the present example, the shape of the third cam drive surface 31R of the third right arm, the lengths of the follower roller 82b and the body section 82a of the power transmission mechanism 82, the lengths of the base section 80a, the left drive section 80L, and the right drive section 80R of the drive member 80, the lengths of the left link member 84L and the right link member 84 (gripping sections 86L and 86R), and the positions of the spindles 83L, 85L, 83R and 85R described above are each set such that when the link mechanism 20 contracts, the gripping section 86L of the left link member 84L, and the gripping section 86R of the right link member 84R make contact with the rim of the substrate 10, which is pressed and moved by the pressing section 6a of the follower mechanism section 6 in the direction of substrate conveyance.

According to the present example with such a structural arrangement, when the link mechanism 20 contracts, as shown in FIG. 8, due to force F from the pressing section 6a of the follower mechanism section 6 in the direction of substrate conveyance, and also due to forces f3 and f4 inward the substrate 10 due to the power from the body section 82a of the power transmission mechanism 82 through the drive member 80 in the directions from the left link member 84L of the left downstream-side pressing section 81L and the right link member 84R of the right downstream-side pressing section 81R to the link mechanism 20. Consequently, the substrate 10 is subjected to the pressing forces from the upstream and downstream sides in the direction of substrate conveyance, whereby the substrate 10 is reliably held (gripped) on the mounting section 5.

The timing when the pressing section 6a of the follower mechanism section 6, the gripping section 86L of the left link member 84L, and the gripping section 86R of the right link member 84R come into contact with the substrate 10 may be simultaneous with when the link mechanism 20 is fully contracted, or may be before (immediately before) the link mechanism 20 is fully contracted. The timing may be appropriately changed depending on the size, arrangement, and configuration of the conveying device and the vacuum device to which the present invention is applied.

In view of gripping the substrate 10 with high precision, a preferred structural arrangement is such that the pressing section 6a of the follower mechanism section 6 makes contact with the rim of the substrate 10 before the gripping section 86L of the left link member 84L and the gripping section 86R of the right link member 84R make contact with the rim of the substrate 10.

In the present example, the gripping section 86L of the left downstream-side pressing section 81L and the gripping section 86R of the right downstream-side pressing section 81R are arranged to be line-symmetrical with respect to a straight line that extends in the direction of substrate conveyance through the center axis of rotation of the first and second drive shafts 11 and 12. It is therefore possible to press and hold (grip) the substrate 10 in a well-balanced manner by the gripping section 86L of the left link member 84L and the gripping section 86R of the right link member 84R.

Moreover, in the present example, the moving distances of the gripping section 86L of the left link member 84L and the gripping section 86R of the right link member 84R are set to be smaller than the moving distance of the follower mechanism section 6 in the direction of substrate conveyance. This makes it possible to set the timing and time at which the gripping section 86L of the left link member 84L and the gripping section 86R of the right link member 84R press the substrate 10, within a predetermined range with respect to the pressing timing of the pressing section 6a of the follower mechanism section 6 to the substrate 10. The substrate 10 can thus be gripped with high precision.

In addition, according to the present example, the sliding portions of the link mechanism are positioned away from the substrate 10 so that it is possible to prevent the surface of the substrate 10 from contamination by dust that is generated by the sliding portions.

The other configuration, operation, and effect are the same as in the foregoing example so that the detailed description thereof will thus be omitted.

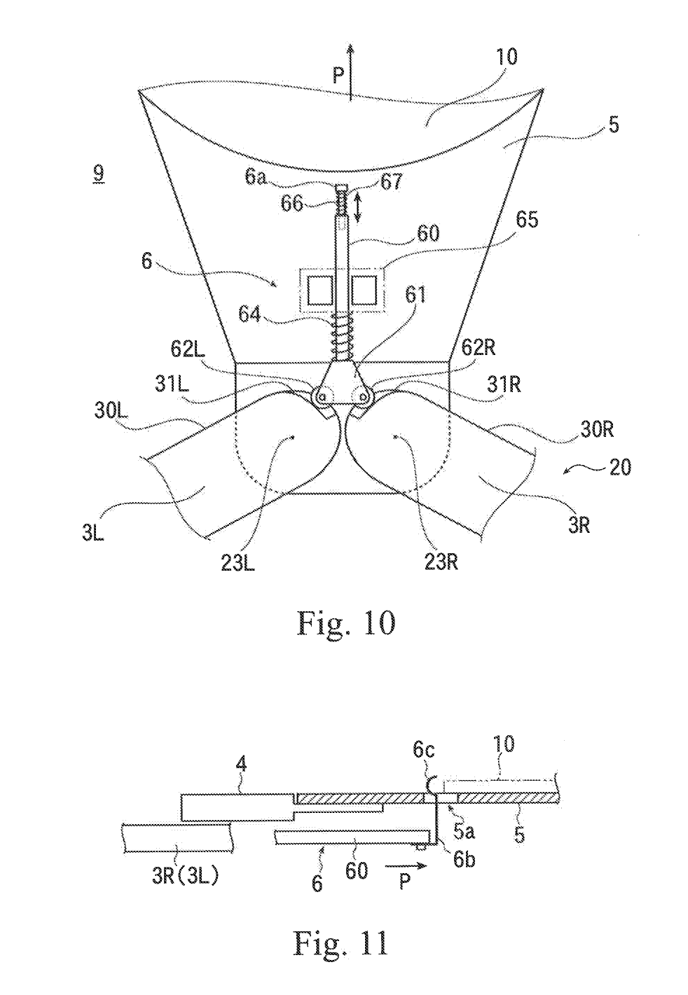

FIGS. 10 to 13 show other examples of the upstream-side pressing mechanism according to the present invention. Parts corresponding to those of the foregoing examples will hereinafter be designated by the same reference numerals, and detailed description thereof will be omitted.

In the examples shown in FIGS. 10 to 13, the base section 70 of the downstream-side pressing mechanism 7, for example, (as shown in FIG. 4) is attached and fixed to the body section 60 of the follower mechanism section 6. For the sake of convenience, a description of the downstream-side pressing mechanism 7 will be omitted here.

FIG. 10 shows an example where the follower mechanism section of the upstream-side pressing mechanism includes a force reducing member for reducing the pressing force of the pressing section.

As shown in FIG. 10, in the present example, a support section 66 of the pressing section 6a of the follower mechanism section 6 is able to move in the extending direction of the body section 60. A compression coil spring (force reducing member) 67 is attached to around the support section 66, between the top end of the body section 60 and the pressing section 6a. The pressing section 6 is able to move toward the body section 60 against the elastic force of the compression coil spring 67 when the top end of the pressing section 6a undergoes force toward the body section 60.

According to the present example having such a structural arrangement, it is possible to adjust the pressing force on the substrate 10 when holding (gripping) the substrate 10. This provides the advantages of an increased design freedom and higher versatility according to various types of objects to be conveyed and the device configuration.

FIG. 11 is a partial sectional side view showing essential parts of another example of the upstream-side pressing mechanism, where the third left arm 3L and the third right arm 3R are located under the power transmission mechanism 4.

As shown in FIG. 11, in the present example, the follower mechanism section 6 of the foregoing configuration is arranged at the top ends of the third left arm 3L and the third right arm 3R. The body section 60 is able to move straight in the direction of substrate conveyance.

A force reducing member 6b is attached to the top end of the body section 60 of the follower mechanism section 6. The force reducing member 6b is made of a plate-shape elastic material of metal (such as, stainless steel), and is arranged upward from the top end of the body section 60.

A pressing section 6c having a, for example, concave shape is provided on the top end of the force reducing member 6b. The pressing section 6c is configured to protrude upward from the mounting section 5 through a hole ha which is provided in the mounting section 5, and so that the concave portion of the pressing section 6c makes contact with or separates from the side portion of the substrate with the movement of the follower mechanism section 6.

According to the present example having such a structural arrangement, it is possible to adjust the pressing force on the substrate 10 when holding (gripping) the substrate 10 as in the foregoing example.

Moreover, the present example may be used, for example, as a wafer pressing mechanism on the lower arm of an arm mechanism that has an upper end effector and a lower end effecter at a small vertical interval, as shown in FIGS. 22 and 23 of U.S. Pat. No. 6,364,599 B1. It should be appreciated that the configuration of FIGS. 2(a), 2(b), 3(a), and 3(b) discussed above may be used as a wafer pressing mechanism on the upper arm of such an arm mechanism.

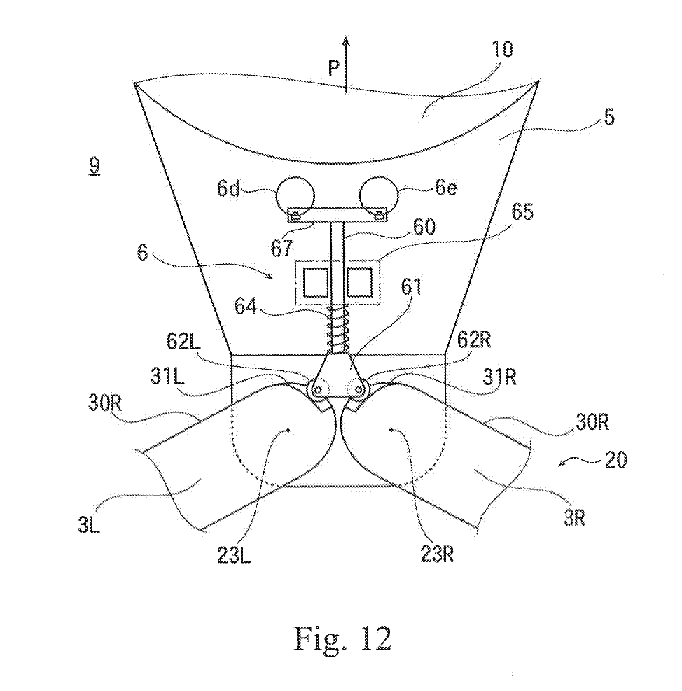

FIG. 12 is a structural outline showing essential parts of yet another example of the upstream-side pressing mechanism, and in more detail, showing an example having a force reducing member for reducing the pressing force of the pressing section of the follower mechanism section.

As shown in FIG. 12, the present example is a modification of the example shown in FIG. 10. For example, an attachment member 67 having a straight bar shape extending in a direction orthogonal to the extending direction of the body section 60 is fixed to the top end of the body section of the body 60 of the follower mechanism section 6. Two force reducing and pressing sections 6d and 6e having a ring and belt shape, made of metal (such as stainless steel), are attached to both ends of the attachment member 67 so as to protrude from the attachment member 67 to the downstream side in the direction of substrate conveyance.

The two force reducing and pressing sections 6d and 6e are formed with the same size and shape, and are arranged to be line-symmetrical with respect to a straight line that extends in the direction of substrate conveyance through the center axis of rotation of the first and second drive shafts 11 and 12.

According to the present example with such a structural arrangement, it is possible to adjust the pressing force on the substrate 10 when holding (gripping) the substrate 10, similar to the example shown in FIG. 10. In addition, since the substrate 10 is pressed by the two force reducing and pressing sections 6d and 6e which are arranged line-symmetrically with respect to the direction of substrate conveyance, there is the advantage of the substrate 10 being held (gripped) in a well-balanced manner.

As in the example shown in FIG. 11, the present example may be configured such that the third left arm 3L, the third right arm 3R, and the follower mechanism section 6 can be located the lower side of the power transmission mechanism 4.

In such a case, it is preferable to provide a hole (not shown) in the mounting section 5 similar to the example shown in FIG. 11, and to dispose an attachment member 68 and the force reducing and pressing sections 6d and 6e above the mounting section 5 through the hole and the force reducing and pressing sections 6d and 6e make contact with or separate from the side portion of the substrate 10.

According to such an example, there is an advantage in that the present example can be used as a wafer pressing mechanism on the lower arm of the arm mechanism that has an upper end effector and a lower end effecter at a small vertical interval, as shown in FIGS. 22 and 23 of U.S. Pat. No. 6,364,599 B1, for example. It should be appreciated that the foregoing configuration of FIG. 12 itself can be used as a wafer pressing mechanism on the upper arm of such an arm mechanism.

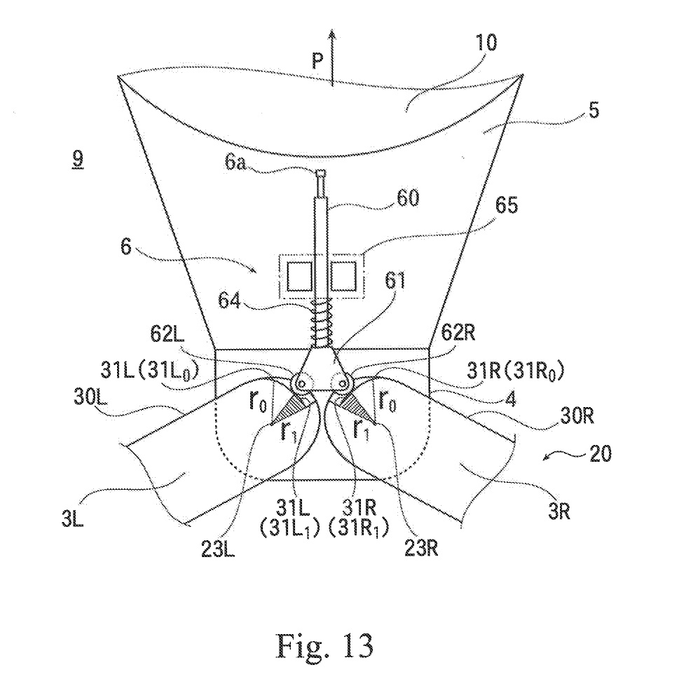

FIG. 13 is a configuration diagram showing essential parts of yet another example of the upstream-side pressing mechanism.

In the foregoing example shown in FIG. 2(b), the cam drive surfaces 31L and 31R of the third left arm 3L and the third right arm 3R are configured such that the amount of displacement r1 on the respective top sides is smaller than the amount of displacement r0 on the respective base sides (r1<r0).

If, however, in the conveying device having a plurality of process chambers (such as, the process chamber 8B as shown) in FIGS. 7(a) to 7(c), the position to transfer the substrate 10 is not always the same. The distances from the center axis of the drive shafts 11 and 12 to the transfer positions in the respective process chambers 8B differ depending on the internal configurations of the process chambers 8B.

If the distance to a transfer position (i.e., if the transfer distance is small), the gap between the edge of the substrate 10 and the pressing section 6a upon the transfer of the substrate 10 may be so small so that there is a possibility that the pressing section 6a may collide with the edge of the substrate 10, and may cause the problems of dust generation and substrate displacement.

To avoid such problems, for example, the cam drive surfaces 31L and 31R of the third left arm 3L and the third right arm 3R an the top end side may be formed to make a constant amount of displacement across a predetermined angle range as shown by the shadowed areas in FIG. 13. That is, the cam drive cam drive surfaces 31L and 31R on the top end side may be formed into an arc-like shape having the same radius as the amount of displacement r1.

With such a configuration, the body section 60 of the follower mechanism section 6 makes no linear movement in the direction of substrate conveyance while the follower rollers 62L and 62R are in contact with the cam drive surfaces 31L and 31R within the range of the radius r1 which is shown shadowed in the diagram, so that the edge of the substrate 10 and the pressing section 6a can be maintained at a non-contact distance regardless of whether the distance for transferring the substrate 1 is small or large; and thus, it is possible to avoid the problems of dust generation and substrate displacement.

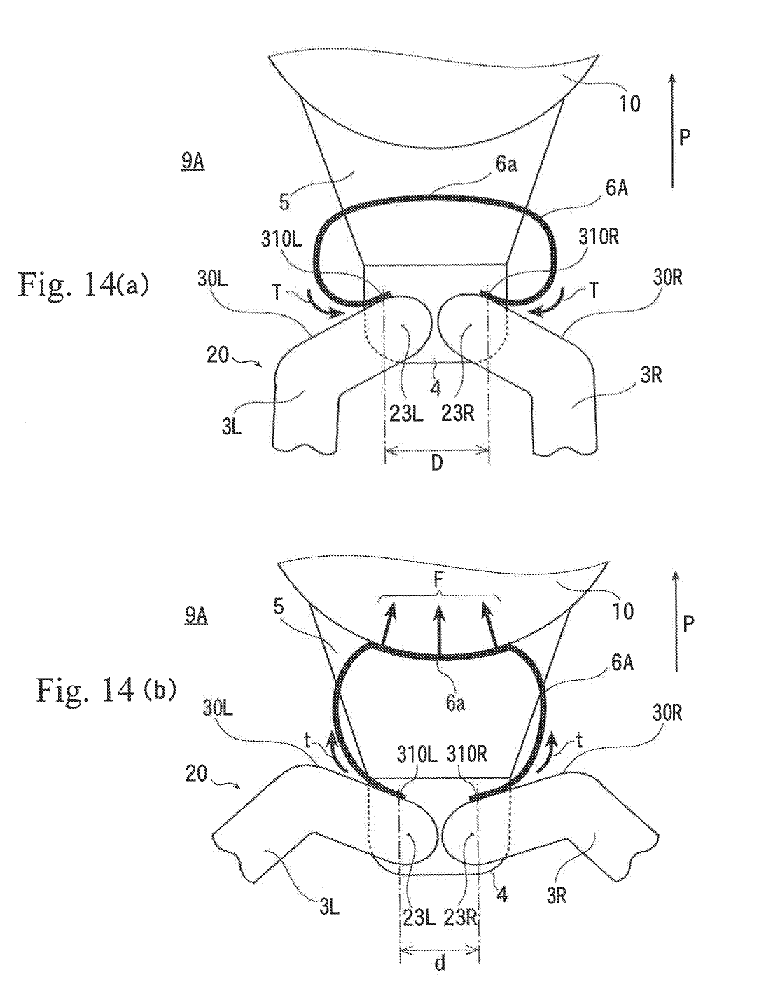

FIGS. 14(a) and 14(b) are configuration diagrams showing yet another example of the upstream-side pressing mechanism. Parts corresponding to those of the foregoing examples will hereinafter be designated by the same reference numerals, and a detailed description thereof will be omitted.

In the present example, the third right arm 3R is provided with the cam drive surface 31R described above, and the downstream-side pressing mechanism 8 (as shown in, e.g., FIG. 8) is attached to the mounting section 5. For the sake of convenience, a description of the downstream-side pressing mechanism 8 will be omitted here.

As shown in FIGS. 14(a) and 14(b), in the present example, an upstream-side pressing member 6A made of a single piece of elastic member is attached across the attachment surface 30L on the mounting section 5 side of the third left arm 3L and the attachment surface 30R on the mounting section 5 side of the third right arm 3R as an upstream-side pressing mechanism 9A.

The upstream-side pressing member 6A is preferably made of a metal material (such as, stainless steel) and is fixed at respective ends to the third left arm 3L and the third right arm 3R by, e.g., screws or the like. The length of the upstream-side pressing member 6A is thereby set so as to form a protruding shape toward the downstream side in the direction of substrate conveyance from the attachment surface 30L on the mounting section 5 side of the third left arm 3L and the attachment surface 30R on the mounting section 5 side of the third right arm 3R.

In the present invention, to prevent the generation of dust in a vacuum ambience, it is preferable that the material of the upstream-side pressing member 6A be selected and the shape and arrangement of the upstream-side pressing member 6A be determined such that the upstream-side pressing member 6A does not make contact with the surface of the power transmission mechanism 4 or the surface of the mounting section 5.

Because of this, it is more preferable for the upstream-side pressing member 6A to be formed in a belt shape with a predetermined width.

The upstream-side pressing member 6A is preferably attached to a position that is set such that a portion of the upstream-side pressing member 6A on the downstream side in the direction of substrate conveyance surely makes contact with the side portion of the substrate 10 above and away from the surface of the mounting section 5.

Referring to FIGS. 14(a) and 14(b), the principle of operation and configuration of the present invention will be described in detail.

In the present example, as shown in FIGS. 14(a) and 14(b), the attachment surface 30L of the third left arm 3L and the attachment surface 30R of the right arm 3R are both configured to be oblique to the direction of surface conveyance when the link mechanism 20 is extended and when the link mechanism 20 contracted.

When the link mechanism 20 is extended, as shown in FIG. 14(a), the angle formed between the attachment surface 30L of the third left arm 3L and the attachment surface 30R of the third right arm 3R is set to, for example, greater than 180 degrees.

In the present invention, though not particularly limited, the distance D between fixing sections 310L and 310R where the upstream-side pressing member 6A is fixed to the attachment surface 30L of the third left arm 3L and the attachment surface 30R of the third right arm 3R shall be greater than the distance between the spindles 23L and 23R on the top end side of the third left arm 3L and the third right arm 3R, for example.

When the link mechanism 20 is contracted, as shown in FIG. 14(b), the angle formed between the attachment surface 30L of the third left arm 3L and the attachment surface 30R of the third right arm 3R is set to, for example, smaller than 1380 degrees.

With such a configuration, when the link mechanism 20 is extended, as shown in FIG. 14(a), the areas near the ends of the upstream-side pressing member 6A laid across the third left arm 3L and the third right arm 3R undergo respective inward revolving forces (moment) T. As a result, the upstream-side pressing member 6A comes to rest in a compressed shape in the direction of substrate conveyance as compared to a perfect circle.

The shape, size, and material of the upstream-side pressing member 6A, as well as the angles of the attachment surfaces 30L and 30R of the third left arm 3L and the third right arm 3R, and the fixing position of the upstream-side pressing member 6A (the distance between the fixing sections 310L and 310R) are set such that the pressing section 6a on the downstream side of the upstream-side pressing member 6A in the direction of substrate conveyance during the extract state does not make contact with the side portion of the substrate 10 to be conveyed.

On the other hand, when the link mechanism 20 is contracted, as shown in FIG. 14(b), the distance d between the fixing sections 310L and 310R where the upstream-side pressing member 6A is fixed to the attachment surface 30L of the third left arm 3L and the attachment surface 30R of the third right arm 3R is smaller than that when the link mechanism 20 is extended (D>d). In addition, the angle formed between the attachment surface 30L of the third left arm 3L and the attachment surface 30R of the third right arm 3R is smaller than 180 degrees. Consequently, the areas near the ends of the upstream-side pressing member 6A laid across the third left arm 3L and the third right arm 3R undergo respective pushing forces (moment) t toward a downstream in the direction of substrate conveyance.

As a result, the portion on the downstream side of the upstream-side pressing member 6 in the direction of substrate conveyance (pressing section 6a) makes contact with the side portion of the substrate 10 to be conveyed, whereby force F can be applied to the side portion of the substrate 10 in the direction of substrate conveyance.

In the present example described above, the upstream-side pressing member 6A is configured as a belt-shaped member, with no sliding portion near the area where the substrate 10 is gripped. This can minimize the generation of dust that may contaminate the substrate 10.

The other configuration, operation, and effect are the same as in the foregoing examples so that a detailed description thereof will thus be omitted.

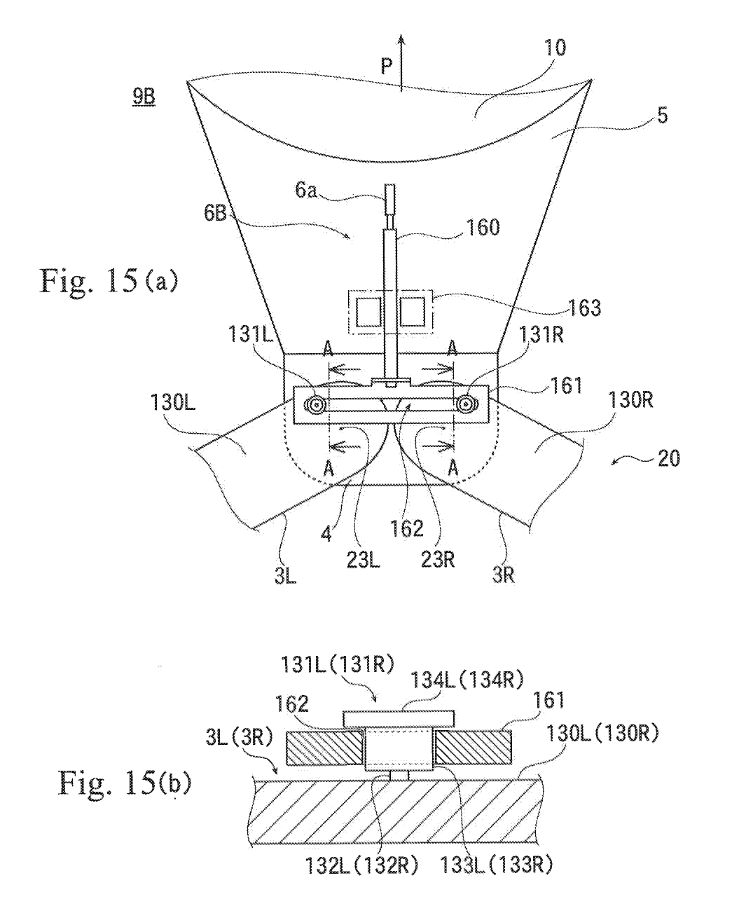

FIG. 15(a) is a configuration diagram showing yet another example of the upstream-side pressing mechanism according to the present invention in its entirety. FIG. 15(b) is a sectional view taken along the lines A-A of FIG. 15(a). Parts corresponding to those of the foregoing examples will hereinafter be designated by the same reference numerals, and a detailed description thereof will be omitted.

In the present example, the base section 70 of the downstream-side press in a mechanism 7 (as shown in, e.g., FIG. 4) is attached and fixed to the body section 160 of the follower mechanism section 6. For the sake of convenience, a description of the downstream-side pressing mechanism 7 will be omitted here.

As shown in FIG. 15(a), in the present example, each of the top ends of the third left arm 3L and the third right, arm 3R is formed in a semicircular shape. Drive support sections 131L and 131R each having a projecting shape (hereinafter, referred to simply as “drive projections”) are provided on front side surfaces 130L and 130R of the third left arm L and the third right arm 3R, respectively. The drive projections 131L and 131R and a follower mechanism section 6B constitute an upstream-side pressing mechanism 9B, which is based on a slide mechanism.

In the present example, it is preferred that the drive projections 131L and 131R be made of a metal material (such as, stainless steel) and located at a predetermined distance from the spindle 23L of the third left arm 3L and the spindle 23R of the third right arm 3R. Here, the drive projections 131L and 131R are arranged on the downstream side of the spindles 23L and 23R of the third left arm 3L and the third right arm 3R in the direction of substrate conveyance.

In the present example, the drive projections 131L and 131R of the third left arm 3L and the third right arm 3R are in line-symmetrical with respect to a straight line that extends in the direction of substrate conveyance through the center axis of rotation of the first and second drive shafts 11 and 12.

The drive projections 131L and 131R of the present example are intended to engage with a long hole 62 of a follower section 61, as later described, and have the same configuration.

As shown in FIG. 15(b), the drive projections 131L and 131R have cylindrical rotating shafts 133L and 133R, which are horizontally rotatably supported about spindles 132L and 132R erected on the front side surfaces 130L and 130R of the third left arm 3L and the third right arm 3R, respectively.

Support sections 134L and 134R having, for example, a disk-like shape with a diameter slightly greater than the diameter of the rotating shafts 133L and 133R are provided on top of the respective rotating shafts 133L and 133R.

The follower mechanism section 6B of the present example, which is made of a metal member (preferably stainless steel or the like) has a body section 160 of a straight bar shape.

The follower section 161 having rectangular plate shape, and extending in a direction orthogonal to the body section 160, for example, is attached to an end of the body section 160 of the follower mechanism section 6B. The follower section 161 has the long hole 162 in its center area in the width direction, for example. The long hole 162 extends straight in the longitudinal direction of the follower section 161.

As shown in FIG. 15(b), the width of the long hole 162 of the follower section 161 is set to be slightly greater than the diameter of the rotating shafts 133L and 133R of the drive projections 131L and 131R, as described above, and smaller than the diameter of the support sections 134L and 134R.

The length of the long hole 162 of the follower section 161 is set to be greater than the maximum distance between the drive projections 131L and 131R, which move with the rotation of the third left arm 3L and the third right arm 3R.

With such a structural arrangement, when the third left arm 3L and the third right arm 3R are rotated, the drive shafts 133L and 133R of the respective drive projections 131L and 131R slide inside and in engagement with the long hole 162 of the follower section 161 so as to press the opening rim on the upstream side or downstream side in the direction of substrate conveyance.

A pressing section 6a having a protruding shape (for example, pin shape) is attached to the other end of the body section 160 of the follower mechanism section 6B. The top end of the pressing section 6a may be coated with a heat resistant resin material (such as PTFE) for avoiding dust generation.

In the present example, as shown in FIG. 15(b), the drive projections 131L and 131R of the third left arm 3L and the third right arm 3R are engaged with the long hole 162 in the follower section 161 of the follower mechanism section 6B. In such a state, the body section 160 of the follower mechanism section 6B is guided by a guide member 163 which is provided on the front side surface of the mounting section 5, for example. The body section 160 is thereby moved straight in the direction of substrate conveyance or in the opposite direction.

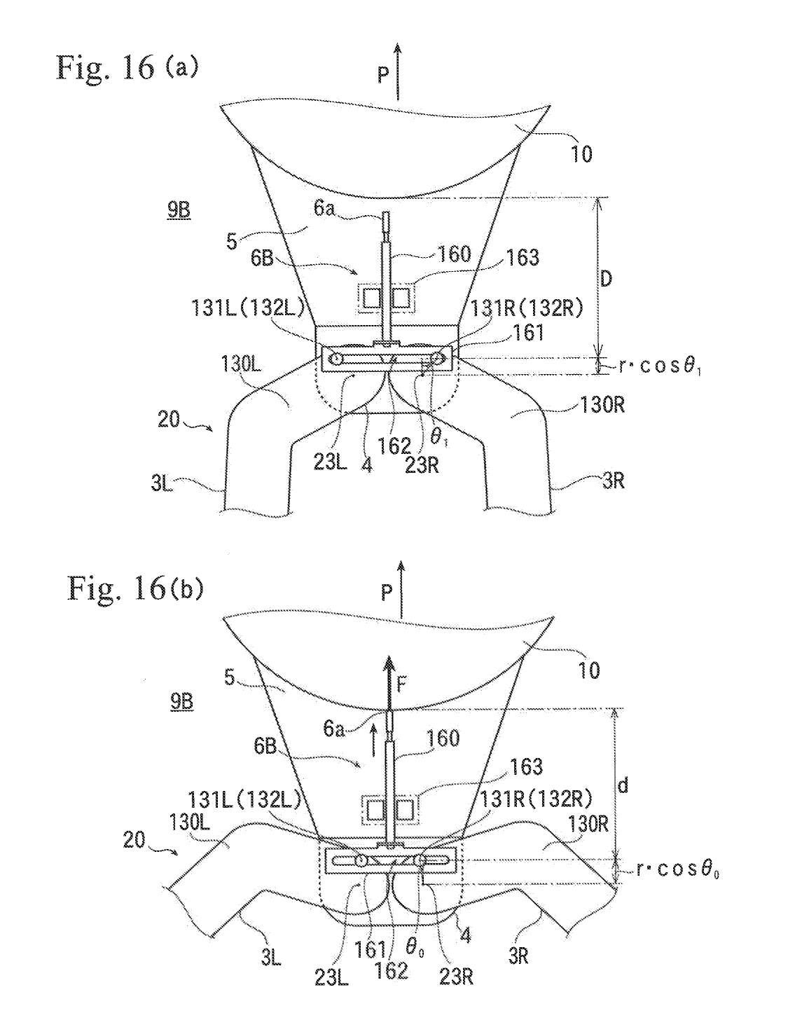

Next, the principle of operation and configuration of the present example will be described in detail in reference to FIGS. 16(a) and 16(b).

Here, for instance, each of the distance between the spindle 23L of the third left arm 3L and the spindle 132L of the drive projection 131L and the distance between the spindle 23R of the third right arm 3R and the spindle 132R of the drive projection 131R is r.

In the present example, when the link mechanism 20 is extended, as shown in FIG. 16(a), the angle formed between the top ends of the third left arm 3L and the third right arm 3R is set to, for example, greater than 180 degrees.

In such a state, the size of the long hole 162 of the follower section 161 and the positions of the drive projections 131L and 131R are determined such that the drive projections 131L and 131R of the third left arm 3L and the third right arm 3R, which engage with the long hole 162 in the follower section 161 of the follower mechanism section 6B, are positioned at respective ends in the long hole 162.

Then, the reference length of the follower mechanism section 6B (here, the distance from the top end of the pressing section 6a to the spindles 132L and 132R of the drive projections 131L and 131R) is set such that the pressing section 6a on the downstream side of the follower mechanism section 6B in the direction of substrate conveyance does not make contact with the side portion of the substrate 10 to be conveyed.

The present example is configured, for example, such that the drive projections 131L and 131R are located outside the spindles 23L and 23R of the third left arm 3L and the third right arm 3R in terms of the direction orthogonal to the direction of substrate conveyance (with an angle θ1 with respect to the direction of substrate conveyance).

On the other hand, when the link mechanism 20 is contracted, as shown in FIG. 16(b), the angle formed between the top ends of the third left arm 3L and the third right arm 3R is set to, for example, smaller than 180 degrees.

In such a state, the drive projections 131L and 131R are rotated and moved to a direction to come closer each other about the spindles 23L and 23R of the third left arm 3L and the third right arm 3R, respectively.

Here, the sizes, shapes, and positions of the above-discussed members are set such that the angle θ₀ with respect to the direction of substrate conveyance has an absolute value smaller than the absolute value of the angle θ₁ with respect to the direction of substrate conveyance when the link mechanism 20 is extended. For example, the settings are made such that the drive projections 131L and 131R are located inside the spindles 23L and 23R of the third left arm 3L and the third right arm 3R in terms of the direction perpendicular to the direction of substrate conveyance.

With such a structural arrangement, when the third left arm 3L and the third right arm 3R are rotated to the contracting directions the drive projections 131L and 131R move to a downstream side in the direction of substrate conveyance to press the opening rim of the long hole 162 of the follower section 61. The follower mechanism section 6B moves downstream in the direction of substrate conveyance to reduce the distance between the pressing section 6a and the side portion of the substrate 10 to be conveyed (r·cos θ₀>r·cos θ₁; i.e., d<D).

As a result, the portion of the follower mechanism section 6B on the downstream side in the direction of substrate conveyance (the top end of the pressing section 6a) comes into contact with the side portion of the substrate 10 to be conveyed, whereby force F in the direction of substrate conveyance can be applied to the side portion of the substrate 10.

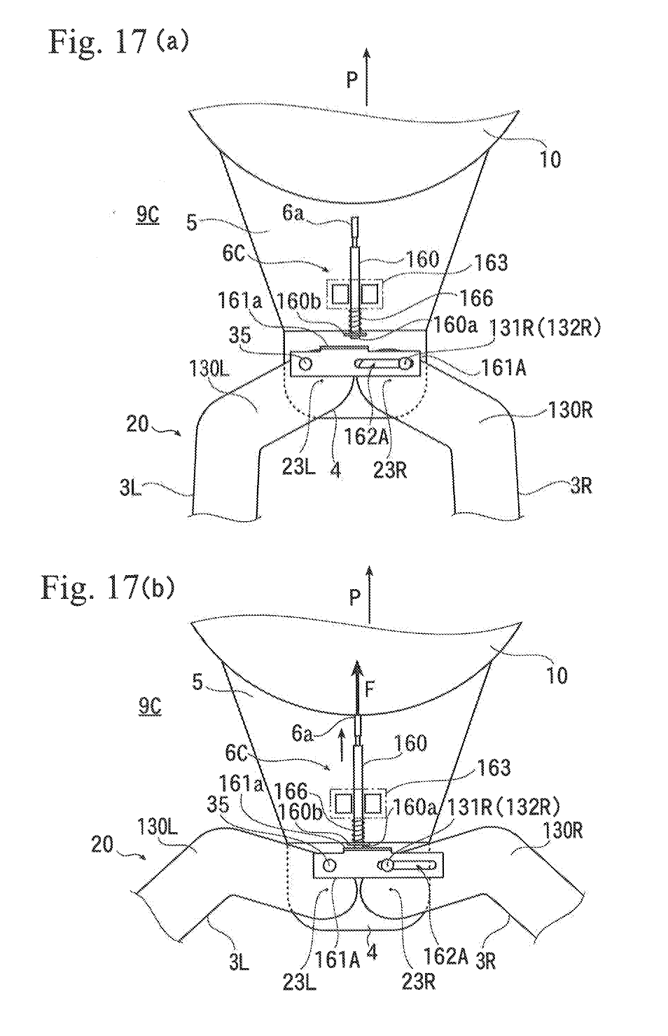

FIGS. 17(a) and 17(b) are diagrams showing the configuration and operation of yet another example of the upstream-side pressing mechanism according to the present invention FIG. 17(a) shows a state where the link mechanism 20 is extended. FIG. 17(b) shows a state where the link mechanism 20 is contracted.

In the present example, the base section 71 of the downstream-side pressing mechanism 7 (as shown in, e.g., FIG. 4) is attached and fixed to the body section 160 of a follower mechanism section 6C, which constitutes an upstream-side pressing mechanism 9C. For the sake of convenience, a description of the downstream-side pressing mechanism 7 will be omitted here.

As shown in FIGS. 17(a) and 17(b), the upstream-side pressing mechanism 9C of the present example is a modification of FIGS. 15(a) and 15(b). A follower section 161A has a long hole 162A which is provided only in an area of the follower section 161A corresponding to the third right arm 3R side.

The follower section 161A is horizontally rotatably supported about a spindle 35, which is provided on the front side surface 130L of the third left arm 3L. In the present example, the spindle 35 is provided in the same position as the foregoing drive projection 131L, and configured such that the follower section 161A rotates about one of its ends (left end).

The long hole 162A of the follower section 161A is formed to extend straight in the longitudinal direction of the follower section 161A. The long hole 162A is configured so as to be engaged with the drive projection 131R (rotating shaft 133R), which is provided on the third right arm 3R.

The follower section 161A of the present example is separate from the body section 160 of the follower mechanism section 6C. A drive contact section 161a, which extends in a direction orthogonal to the direction of substrate conveyance and has a predetermined size, is provided in an area of the follower section 161A on the downstream side in the direction of substrate conveyance.

In the meantime, a follower contact section 160a, which is intended to make contact with the drive contact section 161a of the follower section 161A as described above, is provided at the end of the body section 160 of the follower mechanism section 6C opposite to the pressing section 6a.

A support section 160b is provided on the end of the body section 160 of the follower mechanism section 6C opposite to the pressing section 6a, and a compression coil spring 166 is attached to around the body section 160, between the support section 160b and the guide member 163 as discussed above.

With such a structural arrangement, when the third left arm 3L and the third right arm 3R are rotated to the contracting direction from the extended state shown in FIG. 17(a), the follower section 161A rotates in a clockwise direction about the spindle 35 while the drive projection 31R rotates counterclockwise direction, thereby moving the follower section 161A downstream side in the direction of substrate conveyance.

The drive contact section 161a of the follower section 161A comes into contact with the follower contact section 160a of the body section 160 of the follower mechanism section 6C and presses it toward a downstream side in the direction of substrate conveyance. Consequently, the follower mechanism section 60 moves toward a downstream side in the direction of substrate conveyance against the elastic force of the compression coil spring 166.

As a result, the pressing section 6a on the downstream side of the follower mechanism section 6C in the direction of substrate conveyance comes into contact with the side portion of the substrate to be conveyed; and thus, force F is applied to the side portion of the substrate 10 in the direction of substrate conveyance.

According to the present example such structural arrangement, the follower contact section 160a provided on the pressing section 6a of the follower mechanism section 6C can be pressed against the drive contact section 161a of the follower section 161A for close contact with an appropriate magnitude, so that it is therefore possible to move the follower mechanism section 6C toward downstream in the direction of substrate conveyance, for example, along the guide member 163 with reliability and high precision.

In addition, according to the present example, because the separation of the follower section 161A from the body section 160 makes it possible to slide the body section 160 only in the vicinity of the area where the pressing section 6a comes into contact with the side portion of the substrate 10. This provides the advantage that it is possible to reduce the generation of dust due to the sliding between the guide member 163 and the body section 160.

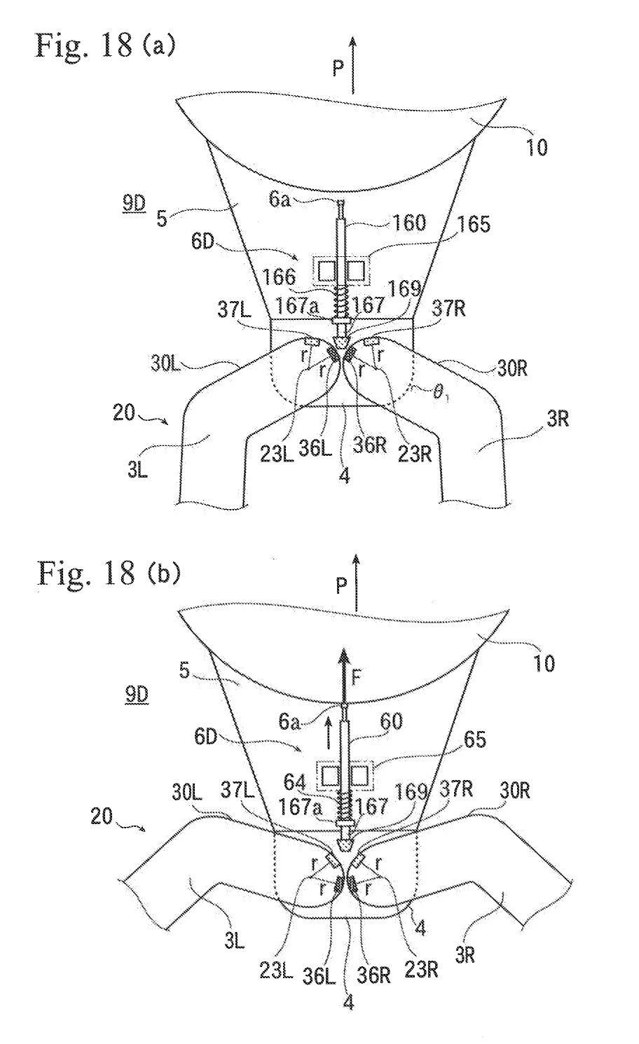

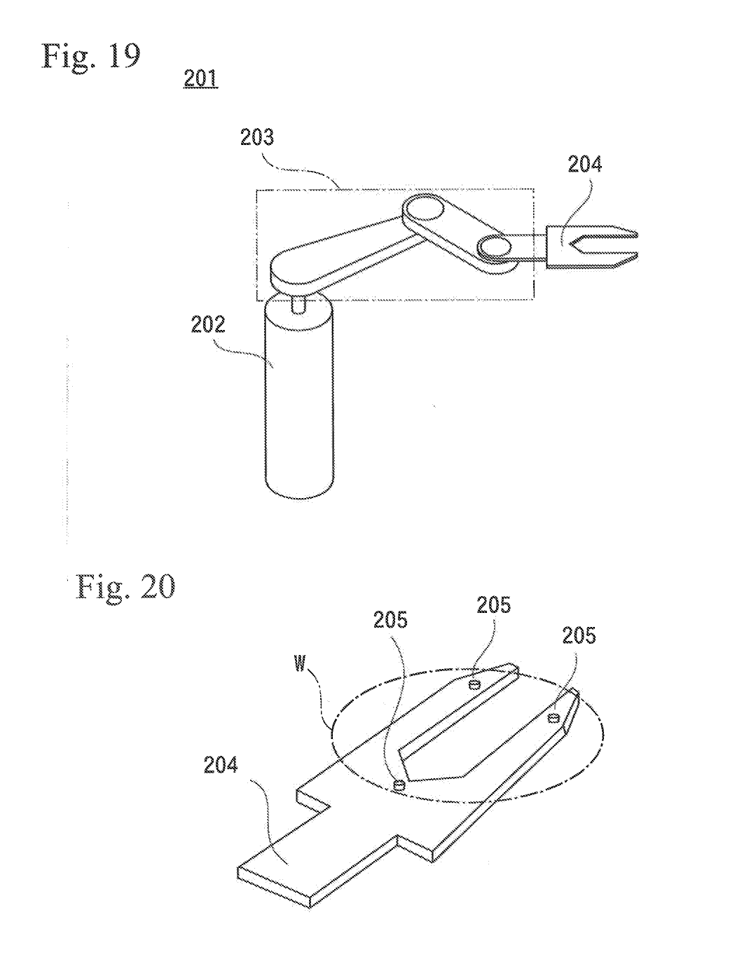

FIGS. 18(a) and 18(b) show the configuration and operation of yet another example of the upstream-side pressing mechanism according to the present invention. Parts corresponding to those of the foregoing examples will hereinafter be designated by the same reference numerals, and a detailed description thereof will be omitted.

In the present example, the base section 71 of the downstream-side pressing mechanism 7 (such as, shown in FIG. 4) is attached and fixed to the body section 60 of a follower mechanism section 6D, which constitutes an upstream-side pressing mechanism 9D. For the sake of convenience, a description of the downstream-side pressing mechanism 7 will be omitted.

As shown in FIGS. 18(a) and 18(b), in the present example, the top portions of the third left arm 3L and the third right arm 3R are each formed in a semicircular shape with a radius of r. First driving magnets 36L and 36R (such as, permanent magnets, for example) are provided at the topmost ends of the third left arm 3L and the third right arm 3R, respectively, with their N poles at the end surfaces, for example.

In addition, second driving magnets 37L and 37R (such as, permanent magnets, for example) are provided in areas of the top ends of the third left arm 3L and the third right arm 3R on the downstream side in the direction of substrate conveyance, respectively, with their S poles at the surfaces, for example.

In the present example, the first driving magnets 36L and 36R and the second driving magnets 37L and 37R are both arranged to be line-symmetrical with respect to a straight line that extends in the direction of substrate conveyance through the center axis of rotation of the first and second drive shafts 11 and 12.

A support member 167, which, for example, includes a latch section 167a having a width greater than the width of the body section 160, is provided on the end of the body section 160 of the follower mechanism section 6D opposite to the side where the pressing section 6a is provided. A follower magnet 169 (such as, a permanent magnet, for example) is provided on the top end of the support member with its S pole, for example, at the end surface (side surface and bottom surface).

A compression coil spring 166 is attached to around the body section 160, between the midsection of the body section 160 of the follower mechanism section 6D and the support member 167 as discussed above. The top portion of the compression coil spring 166 is fixed to the latch section 167a of the support member 167.

Next, the principle of operation and configuration of the upstream-side pressing mechanism according to the present example will be described in detail in reference to FIGS. 18(a) and 18(b).

In the present example, when the link mechanism 20 is extended, as shown in FIG. 18(a), the angle formed between the third left arm 3L and the third right arm 3R is set to, for example, greater than 180 degrees.

On the other hand, when the link mechanism 20 is contracted, as shown in FIG. 18(b), the angle formed between the third left arm 3L and the third right arm 3R is set to, for example, smaller than 180 degrees.

Settings are also made such that the positional relationship (close or far) between the first and second driving magnets 36L, 36R, 37L, and 37R and the follower magnet 169 varies with the relative positional relationship between the third left arm 3L, the third right arm 3R, and the follower mechanism section 6D.

More specifically, the lengths of the body section 160 and the support section 167 of the follower mechanism section 6D, the shape of the third left arm 3L and the third right arm 3R, and the arrangement positions of the first driving magnets 36L and 36R, as described above, are set such that when the link mechanism 20 is extended, as shown in FIG. 18(a), the pressing section 6a on the downstream side of the follower mechanism section 6D in the direction of substrate conveyance does not make contact with the side portion of the substrate 10 to be conveyed and the follower magnet 169 comes close to the first driving magnets 36L and 36R.

On the other hand, the positions of the second driving magnets 37L and 37R are set in an arrangement such that when the link mechanism is contracted, as shown in FIG. 18(b), the second driving magnets 37L and 37R provided on the third left arm 3L and the third right arm 3R are each opposed to the follower magnet of the follower mechanism section 6D.

In such an example, when the link mechanism 20 is extended, as shown in FIG. 18(a), the follower magnet 169 of the follower mechanism section 6D, which is the S pole, comes close to the first driving magnets 36L and 36R of the third left arm 3L and the third right arm 3R, which is the N poles. The follower magnet 169 and the first driving magnets 36L and 36R are therefore attracted to each other by their magnetic forces. Consequently, the follower mechanism section 6D is pulled toward an upstream side in the direction of substrate conveyance, and the pressing section 6a of the follower mechanism section 6D comes to rest; and the pressing section 6a is not in contact with the side portion of the substrate 10 to be conveyed.

On the other hand, when the link mechanism 20 is contracted, as shown in FIG. 18(b), the second driving magnets 37L and 37R, which is the S pole, of the third left arm 3L and the third right arm 3R are each opposed to the follower magnet 169, which is the S pole of the follower mechanism section 6D. The follower magnet 169 and the second driving magnets 37L and 37R are therefore repelled from each other by their magnetic forces, whereby the follower mechanism section 6D is pressed downstream side in the direction of substrate conveyance. As a result, the pressing section 6a on the downstream side of the follower mechanism section 6D in the direction of substrate conveyance makes contact with the side portion of the substrate 10 to be conveyed, and the side portion of the substrate 10 undergoes force F in the direction of substrate conveyance.

According to the present example with such a structural arrangement, the driving force to the follower mechanism section 61 can be transmitted from the third left arm 3L and the third right arm 3R without contact. This can reduce the generation of dust that may contaminate the object to be conveyed.

It should be appreciated that the present invention is not limited to the foregoing embodiment, and various modifications may be made thereto.

For example, in the example shown in FIGS. 2(a) and 2(b) the two adjoining cam drive surfaces 31L and 31R and the two corresponding follower rollers 62L and 62R are combined to constitute the cam mechanism of the upstream-side pressing mechanism 9. However, the present invention is not limited thereto. A single cam drive surface and a single corresponding follower roller may be combined to constitute the cam mechanism of the upstream-side pressing mechanism 9. Three or more cam drive surfaces and three or more corresponding follower rollers may be combined to constitute the cam mechanism of the upstream-side pressing mechanism 9.

In view of holding (gripping) the substrate 10 in a well-balanced manner, however, it is preferred that the adjoining two cam drive surfaces 31L and 31R and the two corresponding follower rollers 62L and 62R be combined to constitute the cam mechanism of the upstream-side pressing mechanism 9 as in the foregoing embodiment.

The cam mechanism of the upstream-side pressing mechanism 9 may be modified as appropriate, (such as, in the shapes of the cam drive surfaces and in the sizes of the follower rollers), depending on the conveying device to which the present invention is applied.

Cam drive surfaces can be formed on a plurality of adjoining link sections that make relative parallel movements with respect to each other (such as, a parallel link arm mechanism) and the upstream-side pressing mechanism 9 moves along the cam drive surfaces and hold the object to be conveyed by the above-described operation.

As for the downstream-side pressing mechanism, in the example shown in FIG. 4, the left drive member 71L and the right drive member 71R (the gripping surfaces 732 in particular) of the left downstream-side pressing section 70L and the right downstream-side pressing section 70R are arranged to be line-symmetrical with respect to a straight line that extends in the of substrate conveyance through the center axis of rotation of the first and second drive shafts 11 and 12. However, the present invention is not limited thereto. The drive members may be arranged to be asymmetrical with respect to the straight line as long as the link mechanism 20 can be pressed toward the substrate 10.

In the example shown in FIG. 4, the two downstream-side pressing sections of a cam type (left downstream-side pressing section 70L and right downstream-side pressing section) are provided. Depending on such factors as the shape and size of the substrate and the device configuration, one, three, or more pressing sections of a cam type can be provided.

Meanwhile, in the example shown in FIG. 8, the gripping section 86L of the left downstream-side pressing section 81L and the gripping section 86R of the right downstream-side pressing section 81R are arranged to be line-symmetrical with respect to a straight line that extends in the direction of substrate conveyance through the center axis of rotation of the first and second drive shafts 11 and 12. However, the present invention is not limited thereto. The gripping sections 86L and 86R can be arranged to be asymmetrical with respect to the straight line as long as the substrate 10 is pressed toward the link mechanism 20.

In the example shown in FIG. 8, there are provided the two downstream-side pressing sections of link type (left downstream-side pressing section 81L and right downstream-side pressing section 81R). Depending on such factors as the shape and size of the substrate and the device configuration, one, three, or more pressing sections of a link type may be provided.

The foregoing embodiment has also dealt with the case where there is provided the upstream-side pressing mechanism that has a movable pressing section. According to the present invention, however, it is possible to provide one, two, or more latch sections on the mounting section instead of the ups ream-side pressing mechanism, so that the latch section(s) and the downstream-side pressing mechanism sandwich and mechanically hold the object to be conveyed from both sides in the direction of substrate conveyance.

Nevertheless, so as to hold the object to be conveyed with higher reliability in order to prevent movement of the object to be conveyed over the mounting section at the time of gripping as much as possible and so as to simultaneously avoid dust generation, it is preferred that the object to be conveyed be sandwiched between and held by the upstream-side pressing mechanism and the downstream-side pressing mechanism, as discussed above.

In addition, the present invention may be used to convey not only a circular substrate (such as, an Si wafer), but also a rectangular substrate (such as, a glass substrate) and various types of substrates, including elliptical and polygonal substrates.

What is claimed is:

1. A conveying device, comprising:
an extensible link mechanism having a plurality of arms to which power from a drive source is transmitted;
a mounting section for mounting an object to be conveyed, the mounting section being connected to an operating tip section of the link mechanism through a drive link section; and
a downstream-side pressing mechanism provided in an area of the mounting section on a downstream side in a direction of substrate conveyance, the downstream-side pressing mechanism making contact with a side portion of the object to be conveyed so as to press the side portion of the objection to be conveyed toward the link mechanism in accordance with an operation of the drive link section of the link mechanism,
wherein the object to be conveyed is sandwiched and held from both sides in the direction of substrate conveyance by the pressing of the downstream-side pressing mechanism.

2. The conveying device according to claim 1, further comprising:
an upstream-side pressing mechanism, which makes contact with the side portion of the object to be conveyed so as to press the object to be conveyed toward a downstream side in the direction of substrate conveyance, provided in an area of the mounting section on an upstream side in the direction of substrate conveyance.

3. The conveying device according to claim 1,
wherein the downstream-side pressing mechanism includes a drive section of cam type, and a downstream-side pressing section of cam type that is driven by the drive section of cam type.

4. The conveying device according to claim 1,
wherein the downstream-side pressing mechanism includes a drive section of a link type, and a downstream-side pressing section of a link type, the downstream-side pressing section being engaged with and driven by the drive section of a link type.

5. The conveying device according to claim 3, further comprising:
two of the downstream-side pressing section,
wherein gripping sections provided on the respective downstream-side pressing sections are arranged to be line-symmetrical with respect to a straight line that extends in the direction of substrate conveyance through center axes of rotation of first and second drive shafts.

6. The conveying device according to claim 2,
wherein the upstream-side pressing mechanism includes
a cam drive surface provided on the drive link section of the link mechanism, and
a follower mechanism section including a pressing section having a follower roller in contact with and capable of following to move the cam drive surface, the pressing section being guided and moved along the direction of substrate conveyance depending on movement of the follower roller.

7. The conveying device according to claim 2,
wherein the upstream-side pressing mechanism includes
a pair of adjoining link members that are provided in the drive link section of the link mechanism and have opposite directions of rotation, and
a belt-shaped pressing means made of an integral elastic member having belt shape is provided across the pair of adjoining link members.

8. The conveying device according to claim 2,
wherein the upstream-side pressing mechanism includes
a drive support section that is provided in the drive link section of the link mechanism, and a follower mechanism section driven by the drive support section, and
wherein the follower mechanism section includes
a follower section having a long-grooved sliding section capable of engagement and sliding with the drive support section, and a pressing section connected to the follower section, the pressing section being guided and moved along the direction of substrate conveyance depending on movement of the drive support section in the long-grooved sliding section of the follower section.

9. The conveying device according to claim 2,
wherein the upstream-side pressing mechanism is configured such that a plurality of driving magnets having different polarities is provided on the drive link section,
wherein a follower magnet having a single polarity is provided on a follower mechanism section, and
wherein each of the plurality of driving magnets and the follower magnet approaches or separates from each other depending on relative positional relationship between the drive link section and the follower mechanism section.

10. A conveying device, comprising:
an extensible link mechanism having a plurality of arms to which power from a drive source is transmitted;
a mounting section for mounting an object to be conveyed and the mounting section is connected to an operating tip section of the link mechanism through a drive link section;
an upstream-side pressing mechanism provided in an area of the mounting section on an upstream side in a direction of substrate conveyance, and the upstream-side pressing mechanism makes contact with a side portion of the object to be conveyed so as to press the object to be conveyed toward a downstream side in the direction of substrate conveyance in accordance with an operation of the drive link section of the link mechanism; and
a downstream-side pressing mechanism provided in an area of the mounting section on a downstream side in the direction of substrate conveyance, and the downstream-side pressing mechanism makes contact with the side portion of the object to be conveyed so as to press the object to be conveyed toward the link mechanism lying on the upstream side in the direction of substrate conveyance in accordance with an operation of the drive link section of the link mechanism, and
wherein the upstream-side pressing mechanism includes
cam drive surfaces respectively provided on a pair of adjoining link members provided in the drive link section of the link mechanism, and
a follower mechanism section having a pair of follower rollers that are capable of making contact with and following the pair of cam drive surfaces, respectively, and a pressing section that moves straight in the direction of substrate conveyance depending on movement of the pair of follower rollers,
wherein a moving distance of the pressing section of the follower mechanism section is set such that the pressing section of the follower mechanism section is not in contact with the side portion of the object to be conveyed when the link mechanism is extended and such that the pressing section of the follower mechanism section is in contact with the side portion of the object to be conveyed when the link mechanism is contracted, and
wherein the object to be conveyed is sandwiched and held from both sides in the direction of substrate conveyance by the pressing of the upstream-side pressing mechanism and the downstream-side pressing mechanism.

11. The conveying device according to claim 10,
wherein the downstream-side pressing mechanism includes
a pair of drive members provided so as to move in the direction of substrate conveyance depending on movement of the follower mechanism section of the upstream-side pressing mechanism,
cam drive surfaces provided on respective one ends of the pair of drive members on the downstream side in the direction of substrate conveyance, and
follower latch members having a gripping section capable of making contact with and following the respective cam drive surfaces of the pair of drive members,
wherein the follower latch members are configured such that each of the gripping sections rotates and moves upstream in the direction of substrate conveyance so as to erect from oblique condition depending on the downstream movement of the pair of drive members in the direction of substrate conveyance, and
wherein a moving distance of a pressing section of the follower latch member is set such that the gripping sections of the follower latch members is not in contact with the side portion of the object to be conveyed when the link mechanism is extended, and such that the gripping sections of the follower mechanism sections is in contact with the side portion of the object to be conveyed when the link mechanism is contracted.

12. A vacuum apparatus, comprising:
a vacuum chamber; and
a conveying device including
an extensible link mechanism having a plurality of arms to which power from a drive source is transmitted,
a mounting section for mounting an object to be conveyed, the mounting section being connected to an operating tip section of the link mechanism through a drive link section, and
a downstream-side pressing mechanism provided in an area of the mounting section on a downstream side in a direction of substrate conveyance,
wherein the downstream-side pressing mechanism makes contact with a side portion of the object to be conveyed so as to press the object to be conveyed toward the link mechanism in accordance with an operation of the drive link section of the link mechanism,
wherein the object to be conveyed is sandwiched and held from both sides in the direction of substrate conveyance by the pressing of the downstream-side pressing mechanism, and
wherein the mounting section of the conveying device is configured to carry in and out of the vacuum chamber.

13. The conveying device according to claim 4, further comprising:
two of the downstream-side pressing section,
wherein gripping sections provided on the respective downstream-side pressing sections are arranged to be line-symmetrical with respect to a straight line that extends in the direction of substrate conveyance through center axes of rotation of first and second drive shafts.
